(19) United States
(12) Patent Application Publication
(10) Pub. No.: US 2022/0116527 A1
(43) Pub. Date: Apr. 14, 2022

(54) IMAGING DEVICE

(71) Applicant: SONY GROUP CORPORATION, TOKYO (JP)

(72) Inventors: GENKI YUZAWA, TOKYO (JP); YOHEI KOYANAGI, KANAGAWA (JP); SHINJI SHIBA, TOKYO (JP); TAIKI UNO, TOKYO (JP); HIROYUKI YOSHIDA, TOKYO (JP)

(21) Appl. No.: 17/309,911

(22) PCT Filed: Dec. 24, 2019
(86) PCT No.: PCT/JP2019/050643

§ 371 Date: Jun. 29, 2021

(30) Foreign Application Priority Data
Jan. 11, 2019 (JP) 2019-003688

(51) Int. Cl. H04N 5/225; G01R 33/07

(52) U.S. Cl. CPC H04N 5/225251; G01R 33/072

(57) ABSTRACT

An imaging device capable of detecting an attitude of a display unit with respect to a body unit is miniaturized. Therefore, an imaging device includes: a display support unit configured to support a display unit that displays an image captured by a body unit; a first arm unit of which one end is connected to the display support unit; a first magnet provided in one of the display support unit and the first arm unit; and a first magnetic sensor provided in the other of the display support unit and the first arm unit. A pivoting state of the display support unit and the first arm unit is variable using a first pivoting axis as a support point axis. The first magnetic sensor receives a magnetic field released from the first magnet and outputs a signal in accordance with the pivoting state of the display support unit and the first arm unit.

### TECHNICAL FIELD

The present technology relates to the technical field of imaging devices In particular, the present technology relates to an imaging device in which a display unit displaying a captured image is provided as a display unit which is movable with respect to a body unit.

### BACKGROUND ART

In imaging devices such as cameras or video cameras, display units on which captured images can be checked are provided. It is preferable to be able to view the captured images displayed on the display units from various angles according to the usage aspects of the imaging devices.

To satisfy the requirement, for example, a technology such as that in PTL 1 has been disclosed.

PTL 1 discloses a configuration in which an attitude of an image display device with respect to a camera body can be changed in accordance with a shooting posture.

### CITATION LIST

### Patent Literature

[PTL 1]

JP 2005-167899 A

### SUMMARY

### Technical Problem

However, the miniaturization of an imaging device is insufficient.

Accordingly, an objective of the present technology is to miniaturize an imaging device in which an attitude of a display unit with respect to a body unit can be detected.

### Solution to Problem

According to an aspect of the present technology, an imaging device includes: a display support unit configured to support a display unit that displays an image captured by a body unit; a first arm unit of which one end is connected to the display support unit; a first magnet provided in one of the display support unit and the first arm unit; and a first magnetic sensor provided in the other of the display support unit and the first arm unit. A pivoting state of the display support unit and the first arm unit is variable using a first pivoting axis as a support point axis. The first magnetic sensor receives a magnetic field released from the first magnet and outputs a signal in accordance with the pivoting state of the display support unit and the first arm unit.

The pivoting state of the display support unit and the first arm unit may indicate, for example, the degree of pivoting of the first arm unit with respect to the display support unit, may indicate the degree of pivoting of the display support unit with respect to the first arm unit, or may indicate an angle formed between the display support unit and the first arm unit. When the pivoting is performed using the first pivoting axis as a support point, the pivoting state may indicate how much the display support unit and the first arm unit are pivoted. The pivoting state may not necessarily indicate a pivoting angle. For example, the pivoting state may indicate how much the first arm unit and the display support unit are presently opened (or a specific degree of opening) or may indicate a relation (or a positional relation) between the first arm unit and the display support unit.

The foregoing imaging device may further include: a second arm unit of which one end is connected to the body unit; a second magnet provided in one of the body unit and the second arm unit; and a second magnetic sensor provided in the other of the body unit and the second arm unit. A pivoting state of the body unit and the second arm unit may be variable using a second pivoting axis as a support point axis. The second magnetic sensor may receive a magnetic field released from the second magnet and output a signal in accordance with the pivoting state of the body unit and the second arm unit.

The pivoting state of the body unit and the second arm unit may be, for example, the degree of pivoting of the second arm unit with respect to the body unit, may indicate degree of pivoting of the body unit with respect to the second arm unit, or may indicate an angle formed between the body unit and the second arm unit. When the pivoting is performed using the second pivoting axis as a support point, the pivoting state may indicate how much the body unit and the second arm unit are pivoted. The pivoting state may not necessarily indicate a pivoting angle. For example, the pivoting state may indicate how much the second arm unit and the body unit are presently opened (or a specific degree of opening) or may indicate a relation (or a positional relation) between the second arm unit and the body unit.

In the foregoing imaging device, the other end which is opposite to the one end of the second arm unit may be connected to the other end which is opposite to the one end of the first arm unit.

That is, the display support unit can be pivoted with respect to the body unit via the first arm unit and the second arm unit.

In the foregoing imaging device, the first magnetic sensor may output a signal in accordance with a positional relation between the first magnetic sensor and the first magnet changing with a change in the pivoting state of the display support unit and the first arm unit.

The signal is output in accordance with the change in the pivoting state of the display support unit and the first arm unit.

In the foregoing imaging device, the second magnetic sensor may output a signal in accordance with a positional relation between the second magnetic sensor and the second magnet changing with a change in the pivoting state of the body unit and the second arm unit.

The signal is output in accordance with the change in the pivoting state of the body unit and the second arm unit.

In the foregoing imaging device, the first magnetic sensor may be provided in the display support unit and the first magnet may be provided in the first arm unit. Compared to the case in which the first magnetic sensor is provided in the first arm unit, thinness of the first arm unit can be achieved when the first magnet is provided in the first arm unit.

In the foregoing imaging device, the first magnetic sensor and the first magnet may be disposed close to the first pivoting axis.

When the first magnetic sensor and the first magnet are disposed close to the first pivoting axis, the first magnetic sensor is disposed close to the first magnet.

In the foregoing imaging device, a distance between the first pivoting axis and the first magnetic sensor may be equal to or less than half of a distance between the first pivoting axis and a free end of the display support unit with respect to the first pivoting axis.

For example, when the imaging device includes another magnet different from the first magnet, it is easy to have an arrangement in which the magnet closest to the first magnetic sensor is always the first magnet.

The foregoing imaging device may further include a control unit configured to perform display control of the image. The control unit may perform display control of the display unit based on the signal output by the first magnetic sensor and the signal output by the second magnetic sensor.

When the display control of the display unit is performed with switching of the photographic mode, an image appropriate for the photographic mode is displayed on the display unit.

The foregoing imaging device may further include a control unit configured to perform display control of the image. The control unit may perform display control to reversely display an image displayed on the display unit based on the signal output by the first magnetic sensor and the signal output by the second magnetic sensor.

The orientation of the captured image displayed on the display unit can be set to be appropriate in accordance with the switching of the photographic mode.

In the foregoing imaging device, the first and second magnetic sensors may be different types of magnetic sensors.

Thus, appropriate disposition can be realized in accordance with the types of magnetic sensors.

In the foregoing imaging device, the first magnetic sensor may be an MR sensor and the second magnetic sensor may be a Hall sensor.

When a known technology is used with a plurality of types of magnetic sensors, it is not necessary to examine basic characteristics to ascertain performance of each sensor.

In the foregoing imaging device, the second magnetic sensor may be provided in the body unit and the second magnet may be provided in the second arm unit. Compared to the case in which the second magnetic sensor is provided in the second arm unit, thinness of the second arm unit can be achieved when the second magnet is provided in the second arm unit.

In the foregoing imaging device, the second magnetic sensor and the second magnet may be disposed close to the second pivoting axis.

When the second magnetic sensor and the second magnet are disposed close to the second pivoting axis, the second magnetic sensor is disposed close to the second magnet.

In the foregoing imaging device, a distance between the second pivoting axis and the second magnetic sensor may be equal to or less than half of a distance between the second pivoting axis and a free end of the second arm unit with respect to the second pivoting axis.

For example, when the imaging device includes another magnet different from the second magnet, it is easy to have an arrangement in which the magnet closest to the second magnetic sensor is always the second magnet.

In the foregoing imaging device, the display support unit may be movable between an unfolded position of being unfolded with respect to the body unit and a folded position of being folded with respect to the body unit. The second magnetic sensor may be disposed at a position not superimposed with the first magnet in a front view of the display unit at the folded position of the display support unit. The folded position is, for example, a position at which the second arm unit, the first arm unit, and the display support unit are all housed in the body unit. In other words, the folded position can also be said to be a state in which the second arm unit, the first arm unit, and the display support unit are integrated with the body unit.

The foregoing imaging device may further include a third magnet provided in one of the body unit and the display support unit; and a third magnetic sensor provided in the other of the body unit and the display support unit. The third magnetic sensor may receive a magnetic field released from the third magnet and output a signal in accordance with a distance between the body unit and the display support unit. For example, a state in which the body unit is close or not close to the display support unit can be detected in accordance with the signal output by the third magnetic sensor.

In the foregoing imaging device, the display support unit may be movable between an unfolded position of being unfolded with respect to the body unit and a folded position of being folded with respect to the body unit. The third magnetic sensor may be disposed at a position not superimposed with the first and second magnets in a front view of the display unit at the folded position of the display support unit. In the folded position, the third magnetic sensor is disposed at the position not superimposed with the first magnet and the second magnet. Thus, the influence of the magnetic fields of the first magnet and the second magnet on the third magnetic sensor is small.

The foregoing imaging device may further include a metal unit provided in one of the body unit and the display support unit; and a fourth magnet provided in the other of the body unit and the display support unit. The display support unit may be movable between an unfolded position of being unfolded with respect to the body unit and a folded position of being folded with respect to the body unit. The fourth magnet may be disposed at a position superimposed with none of the first, second, and third magnetic sensors in a front view of the display unit at the folded position of the display support unit.

When the metal unit and the fourth magnet corresponding thereto are provided, the display support unit can be reliably housed in the body unit.

The foregoing imaging device may further include a flexible substrate electrically connecting the display unit to the body unit. The first magnetic sensor may be connected to the flexible substrate.

For example, the flexible substrate is wired along the first arm unit and the second arm unit, the flexible substrate is bent and stretched in accordance with the pivoting state of the first arm unit and the second arm unit.

### BRIEF DESCRIPTION OF DRAWINGS

FIG. 1 is a perspective view illustrating an imaging device according to an embodiment of the present technology.

FIG. 2 is a perspective view illustrating the imaging device as viewed from another direction according to the embodiment of the present technology.

FIG. 3 is a perspective view illustrating first and second arm units.

FIG. 4 is a schematic side view illustrating a state in which an angle formed between the first arm unit and a display support unit is a minimum.

FIG. 5 is a schematic side view illustrating a state in which an angle formed between the first arm unit and a display support unit is the maximum.

FIG. 6 is a schematic side view illustrating a state in which an angle formed between a body unit and the second arm unit is a minimum.

FIG. 7 is a schematic side view illustrating a state in which an angle formed between a body unit and the second arm unit is the maximum.

FIG. 8 is a schematic side view illustrating a state in which an angle formed between the first and the second arm units is the minimum.

FIG. 9 is a schematic side view illustrating a state in which an angle formed between the first and the second arm units is the maximum.

FIG. 10 is a schematic side view illustrating a state in which a display support unit is housed in a housing depression unit.

FIG. 11 is a schematic side view illustrating a state in which the display support unit, the first arm unit, and the second arm unit are unfolded at a maximum.

FIG. 12 is a schematic sectional view illustrating a state in which the display support unit is pivoted with respect to the first arm unit at a maximum.

FIG. 13 is a schematic sectional view illustrating a state in which the display support unit is pivoted by about 90 degrees with respect to the first arm unit.

FIG. 14 is a schematic sectional view illustrating a state in which the display support unit is not pivoted with respect to the first arm unit.

FIG. 15 is a schematic sectional view illustrating a state in which the second arm unit is pivoted with respect to the body unit at a maximum.

FIG. 16 is a schematic sectional view illustrating a state in which the second arm unit is pivoted with respect to the body unit.

FIG. 17 is a schematic sectional view illustrating a state in which the second arm unit is not pivoted with respect to the body unit.

FIG. 18 is a schematic sectional view illustrating a state before the display support unit is housed in the housing depression unit.

FIG. 19 is a schematic sectional view illustrating a state in which the display support unit is housed in the housing depression unit.

FIG. 20 is a schematic rear view illustrating an example of disposition of a magnet and a magnetic sensor.

FIG. 21 is a schematic side view illustrating an example of disposition of a magnet and a magnetic sensor.

FIG. 22 is a schematic rear view illustrating an example of disposition of a second magnetic sensor and a flexible substrate.

FIG. 23 is a diagram illustrating a control configuration.

FIG. 24 is a table illustrating a relation between combination of output signals of sensors and a photographic mode.

FIG. 25 is a perspective view illustrating the imaging device in a fully housed state.

FIG. 26 is a diagram illustrating an example of a captured image displayed on the display unit.

FIG. 27 is a side view illustrating a first low angle photographic mode.

FIG. 28 is a perspective view illustrating the first low angle photographic mode.

FIG. 29 is a side view illustrating a second low angle photographic mode.

FIG. 30 is a perspective view illustrating the second low angle photographic mode.

FIG. 31 is a side view illustrating a high angle photographic mode.

FIG. 32 is a perspective view illustrating the high angle photographic mode.

FIG. 33 is a diagram illustrating another example of the captured image displayed on the display unit.

### DESCRIPTION OF EMBODIMENTS

Hereinafter, an embodiment will be described in the following order with reference to the appended drawings.

<1. Configuration of imaging device>

<2. Pivoting range>

<3. Detection of pivoting state>

<3-1. Pivoting state of display support unit and first arm unit>

<3-2. Pivoting state of body unit and second arm unit>

<3-3. Pivoting state of body unit and display support unit>

<4. Disposition of magnet and magnetic sensor>

<6. Relation between photographic mode and detection state of each magnetic sensor>

<7. Conclusion>

<8. Present technology>

### 1. Configuration of Imaging Device

An imaging device 1 according to the embodiment will be described with reference to the appended drawings. In the following description, the front, rear, right, and left, top, and bottom are mentioned with a subject side as a “front side”.

In the embodiment to be described below, the imaging device according to the present technology is applied to a digital camera that includes a collapsible type lens, but the application scope of the present technology is not limited to the digital camera. The embodiment can be applied to an imaging device such as a camera or a video camera that includes a detachable lens unit. Of course, a camera that includes a detachable collapsible type lens unit may be used. That is, the embodiment can be broadly applied to various imaging devices including device bodies and monitors that are pivotable with respect to the device bodies.

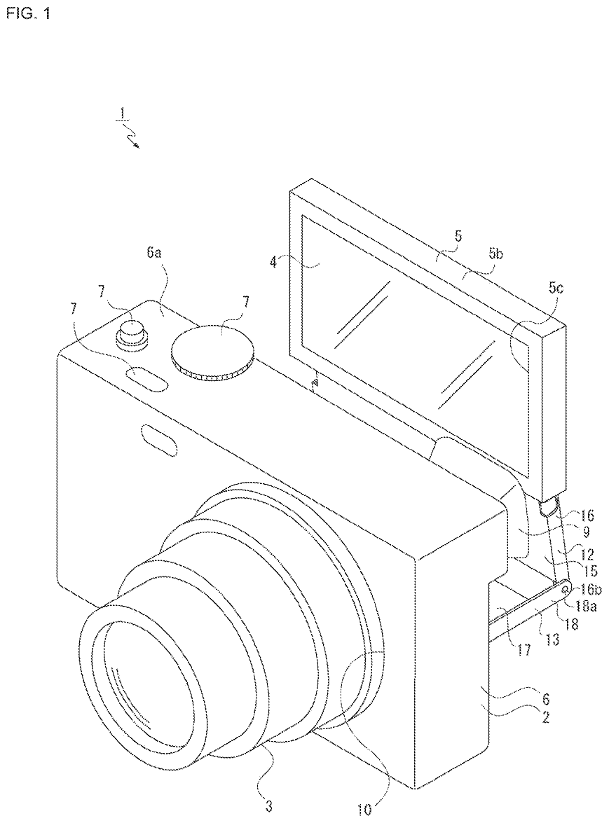

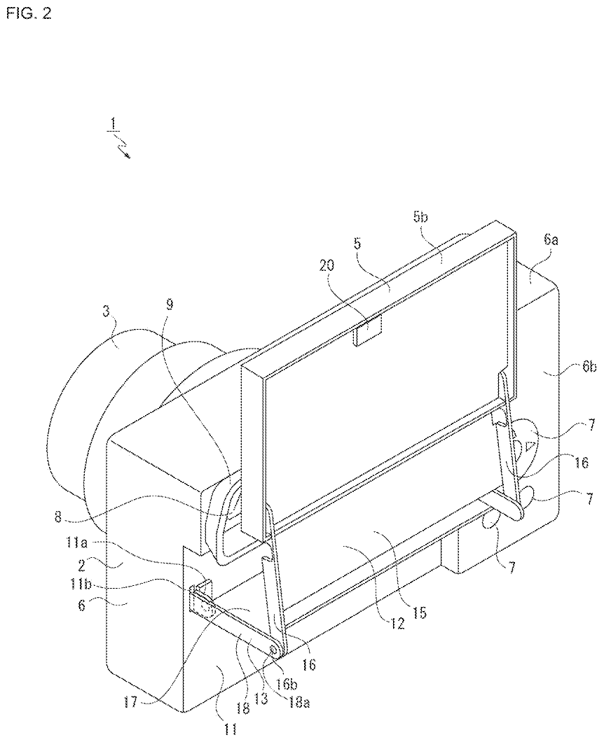

As illustrated in FIGS. 1 and 2, the imaging device 1 includes a body unit 2 that includes an imaging element, a collapsible type imaging lens 3 that is mounted on the front surface of the body unit 2, a display unit 4 that can display a captured image captured by the imaging lens 3, and a display support unit 5 that supports the display unit 4.

The body unit 2 is formed by disposing each unit necessary inside or outside of a casing 6.

In the casing 6, various operational units 7 are provided on a top surface 6a and a rear surface 6b.

As the operational units 7, for example, a power button, a shutter button, a mode switching knob, and the like are provided. An operator for performing various operations on a captured image displayed on the display unit 4 is also provided as the operational unit 7 mainly on the rear surface 6b.

As illustrated in FIG. 2, for example, a substantially rectangular finder window 8 is formed on the rear surface 6b of the casing 6 and an eyepiece 9 is provided around the finder window 8 to surround the finder window 8.

The eyepiece 9 is formed in a tubular shape that has a diameter increasing backwards and has a function of protecting the finder window 8 and reducing the incidence of external light on the finder window 8.

As illustrated in FIG. 1, a disposition hole 10 in which the imaging lens 3 is disposed is provided on the front surface 6c of the casing 6.

A lens group (not illustrated) of a zoom lens, a focus lens, and the like is disposed inside the casing 6 or in the imaging lens 3.

In the casing 6, an imaging element, various electrical circuits, a computer such as a microcomputer performing various kinds of control, a storage unit, and the like are also disposed.

A substantially rectangular housing depression unit 11 in which the display unit 4 and the display support unit 5 are housed is formed on the rear surface 6b of the casing 6 (see FIG. 2).

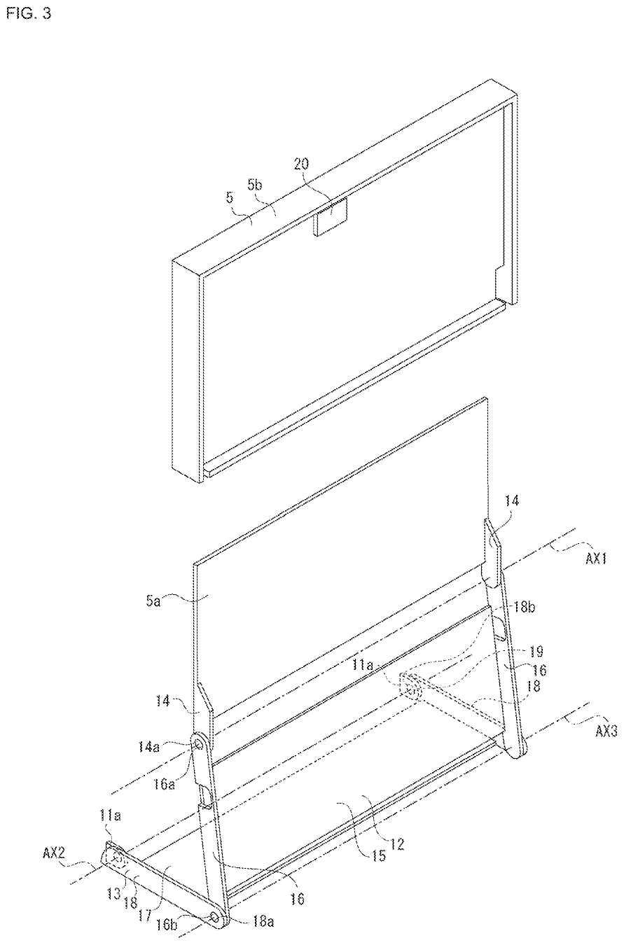

In the housing depression unit 11, two mounting protrusions 11a protruding backwards are provided (see FIGS. 2 and 3).

A mounting protrusion 11a slit 11b is formed at a position adjacent in the right and left directions of the mounting protrusion 11a in the mounting depression unit 11.

The slit 11b is a depression opened backwards.

A lower surface of the slit 11b is a regulation surface 11c for regulating pivoting of the second arm unit 13 with respect to the mounting protrusion 11a of the second arm unit 13 to be described below.

The display support unit 5 is mounted on the mounting protrusion 11a via the first arm unit 12 and the second arm unit 13 (see FIG. 2).

The display support unit 5 includes a plate 5a formed in a substantially rectangular thin plate shape and formed of a metal or the like and a support body unit 5b formed of a resin or the like to cover the plate 5a (see FIG. 3). FIG. 2 illustrates a state in which a decorative sheet is provided in the display support unit 5 so that the plate 5a cannot be viewed. Each drawing subsequent to FIG. 3 illustrates the display support unit 5 or the plate 5a in which the decorative sheet is appropriately omitted.

Protrusions 14 protruding in a direction orthogonal to the plate 5a are formed both right and left ends of the plate 5a.

In each of the protrusions 14, protrusion shafts 14a protruding outside in the right and left directions are formed.

The plate 5a and the protrusions 14 can be formed, for example, by bending one thin metal plate.

In the display support unit 5, a disposition depression 5c in which the display unit 4 is disposed is formed (see FIG. 1).

The first arm unit 12 includes a first base 15 that has a substantially rectangular plate formed of a thin metal or the like and has a largest area and two first protrusions 16 that protrude in a direction orthogonal to the first base 15 from both right and left ends of the first base 15.

A first shaft hole 16a penetrated in the right and left directions is formed at one end of each of the two first protrusions 16. The protrusion shaft 14a formed in the protrusion 14 of the plate 5a of the display support unit 5 is inserted through the first shaft hole 16a and is retained so that the display support unit 5 is pivotable with respect to the first arm unit 12. A constant frictional force acts on the pivoting of the display support unit 5 with respect to the first arm unit 12 so that pivoting does not naturally occur.

At the end opposite to the end at which the first shaft hole 16a of the first protrusion 16 is formed, each first shaft 16b protruding outside in the right and left directions is formed.

In the second arm unit 13, a second base 17 that has a substantially rectangular plate formed of a thin metal or the like and has a largest area and second protrusions 18 that each continue to both right and left ends of the second base 17 and are bent to be substantially orthogonal to the second base 17 are formed.

A second shaft hole 18a penetrated in the right and left directions is formed at each of the ends of the two second protrusions.

The two first shafts 16b formed in the first protrusions 16 are inserted through the second shaft holes 18a and are retained, so that the first arm unit 12 is pivotable with respect to the second arm unit 13. A constant frictional force acts on the pivoting of the first arm unit 12 with respect to the second arm unit 13 so that pivoting does not naturally occur.

At an end opposite to the end at which the second shaft hole 18a of the second protrusion 18 of the second arm unit 13 is formed, each second shaft 18b protruding inwards in the right and left directions is formed.

Two mounting protrusions 11a provided in the housing depression unit 11 are protrusions that are provided separately in the right and left directions and protrude backwards. A shaft hole 19 penetrated in the right and left directions is formed in each mounting protrusion 11a.

The two second shafts 18b formed in the second arm unit 13 are inserted through the shaft holes 19 and are retained so that the second arm unit 13 is pivotable with respect to the body unit 2. A constant frictional force acts on the pivoting of the second arm unit 13 with respect to the body unit 2 so that pivoting does not naturally occur.

A straight line extending in the right and left directions and passing a substantial center of the two protrusion shafts 14a is a first pivoting axis AX1. That is, pivoting of the display support unit 5 with respect to the first arm unit 12 is performed using the first pivoting axis AX1 as a support point. In other words, a pivoting state of the first arm unit 12 and the display support unit 5 is variable using the first pivoting axis AX1 as the support point.

A straight line extending in the right and left directions and passing a substantial center of the two second shafts 18b is a second pivoting axis AX2. That is, pivoting of the second arm unit 13 with respect to the body unit 2 is performed using the second pivoting axis AX2 as a support point. In other words, a pivoting state of the body unit 2 and the second arm unit 13 is variable using the second pivoting axis AX2 as the support point.

A straight line extending in the right and left directions and passing a substantial center of the two first shafts 16b is a third pivoting axis AX3. That is, pivoting of the first arm unit 12 with respect to the second arm unit 13 is performed using the third pivoting axis AX3 as a support point. In other words, a pivoting state of the first arm unit 12 and the second arm unit 13 is variable using the third pivoting axis AX3 as the support point.

A state of the imaging device 1 illustrated in FIGS. 1 and 2 is a state in which the second arm unit 13 is pivoted with respect to the body unit 2 at a maximum and a state in which the first arm unit 12 is pivoted with respect to the second arm unit 13 at a maximum, and is further a state in which the display support unit 5 is pivoted with respect to the first arm unit 12 to a maximum. In the following description, this state is referred to as a “fully unfolded state”.

A state in which the second arm unit 13, the first arm unit 12, and the display support unit 5 are all housed in the housing depression unit 11 is referred to as a “fully housed state”.

### 2. Pivoting Range

A movable range is provided in each of the pivoting of the display support unit 5 with respect to the first arm unit 12 in which the first pivoting axis AX1 is a support point, the pivoting of the second arm unit 13 with respect to the body unit 2 in which the second pivoting axis AX2 is a support point, and the pivoting of the first arm unit 12 with respect to the second arm unit 13 in which the third pivoting axis AX3 is a support point.

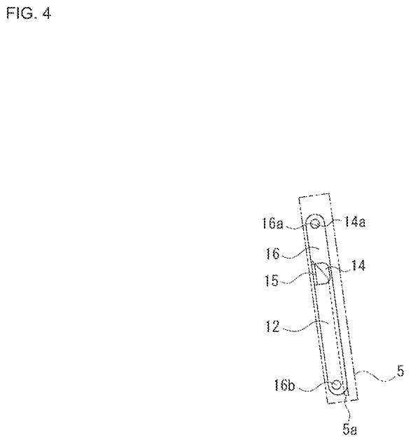

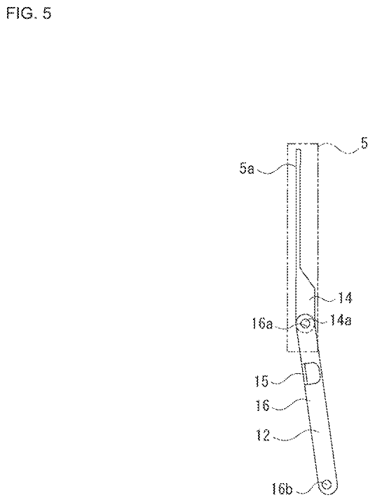

FIGS. 4 and 5 illustrate a range of the pivoting of the display support unit 5 with respect to the first arm unit 12 in which the first pivoting axis AX1 is a support point.

FIG. 4 illustrates a state in which an angle formed between the first arm unit 12 and the display support unit 5 (the plate 5a) is a minimum. As illustrated, the angle formed between the first arm unit 12 and the display support unit 5 is about 0 degrees.

FIG. 5 illustrates a state in which an angle formed between the first arm unit 12 and the display support unit 5 (the plate 5a) is the maximum. As illustrated, the angle formed between the first arm unit 12 and the display support unit 5 is an angle (for example, 172 degrees) slightly smaller than 180 degrees.

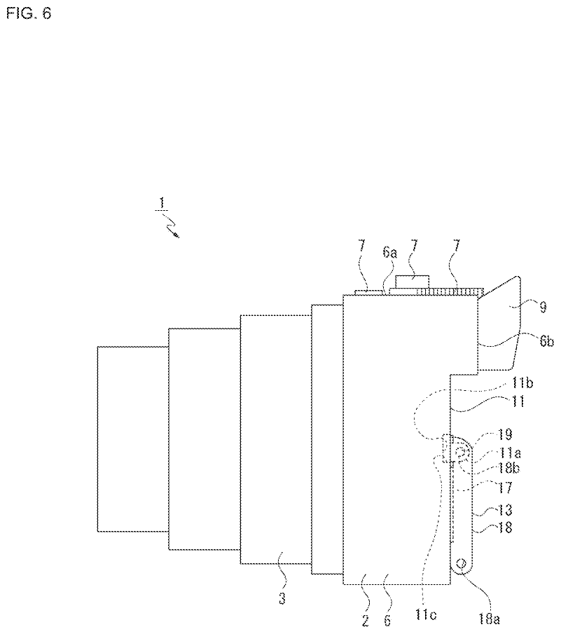

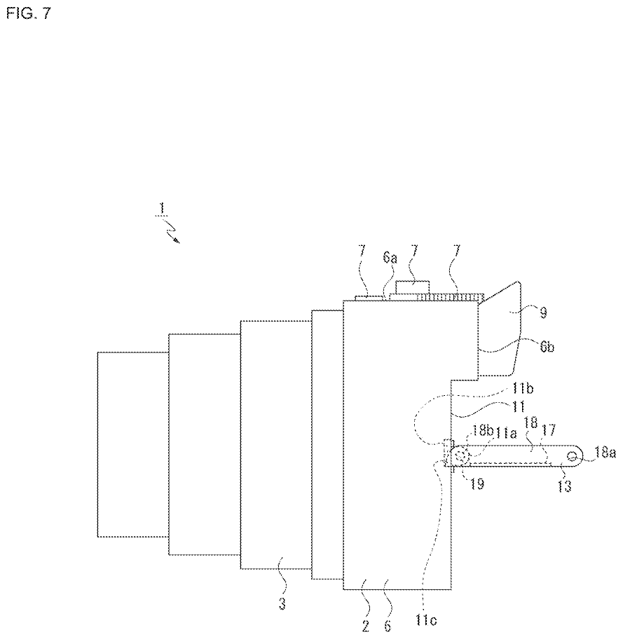

FIGS. 6 and 7 illustrate a range of the pivoting of the second arm unit 13 with respect to the body unit 2 in which the second pivoting axis AX2 is a support point. FIG. 6 illustrates a state in which an angle formed between the housing depression unit 11 and the second arm unit 13 of the body unit 2 is a minimum. As illustrated, the angle formed between the body unit 2 and the second arm unit 13 is about 0 degrees.

FIG. 7 illustrates a state in which an angle formed between the housing depression unit 11 and the second arm unit 13 of the body unit 2 is the maximum. As illustrated, the angle formed between the body unit 2 and the second arm unit 13 is about 90 degrees.

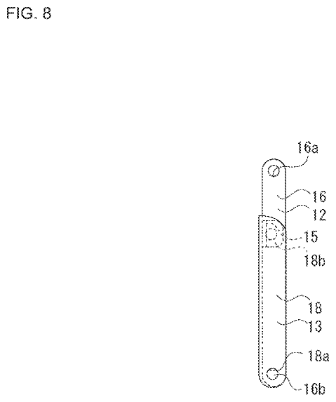

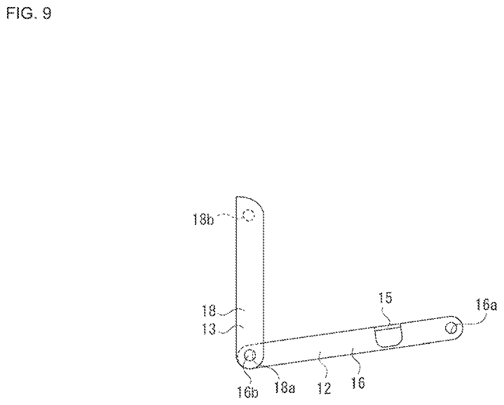

FIGS. 8 and 9 illustrate a range of the pivoting of the first arm unit 12 with respect to the second arm unit 13 in which the third pivoting axis AX3 is a support point. FIG. 8 illustrates a state in which an angle formed between the second arm unit 13 and the first arm unit 12 is the minimum. As illustrated, the angle formed between the second arm unit 13 and the first arm unit 12 is about 0 degrees.

FIG. 9 illustrates a state in which an angle formed between the second arm unit 13 and the first arm unit 12 is the maximum. As illustrated, the angle formed between the second arm unit 13 and the first arm unit 12 is an angle (for example, 82 degrees) slightly smaller than 90 degrees.

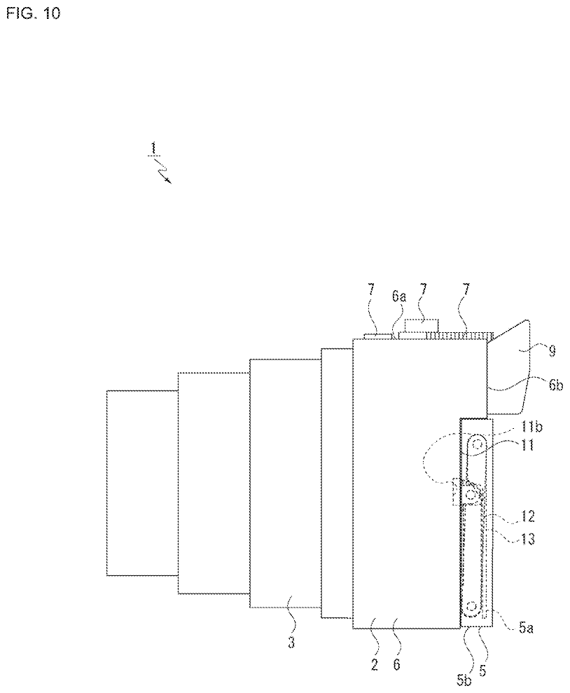

When the minimum angle formed between the first arm unit 12 and the display support unit 5 is about 0 degrees, the minimum angle formed between the body unit 2 and the second arm unit 13 is about 0 degrees, and the minimum angle formed between the second arm unit 13 and the first arm unit 12 is about 0 degrees, the display support unit 5, the first arm unit 12, and the second arm unit 13 are housed in the housing depression unit 11 of the body unit 2 in a substantially superimposing state in a side view (see FIG. 10).

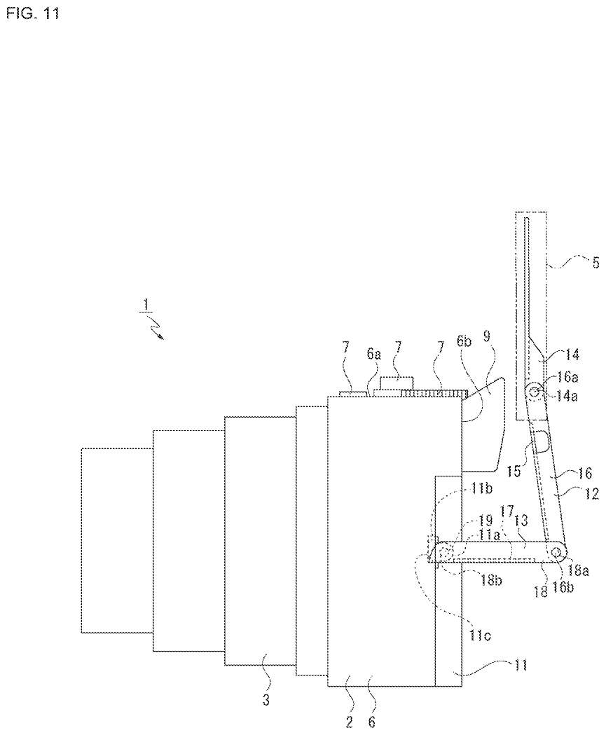

When the angle formed between the first arm unit 12 and the display support unit 5 is the maximum (about 172 degrees), the angle formed between the body unit 2 and the second arm unit 13 is the maximum (about 90 degrees), and the angle formed between the second arm unit 13 and the first arm unit 12 is the maximum (about 82 degrees), the display unit 4 supported by the display support unit 5 at the maximum angle of all the pivoting states is oriented substantially frontwards and a form optimum for a selfie mode can be taken (see FIG. 11).

When each unit is at the maximum angle, the display unit 4 is located above the body unit 2. Therefore, when the selfie mode is applied, the display unit 4 can be reliably viewed from a photographer located on the side of the imaging lens 3 in the selfie mode so that the selfie mode is appropriate.

Although not illustrated, a regulation unit or a regulated unit that regulates predetermined pivoting or more in which the first pivoting axis AX1 is a support point is provided one or both of the first arm unit 12 and the display support unit 5. A regulation unit or a regulated unit that regulates predetermined pivoting or more in which the third pivoting axis AX3 is a support point is provided one or both of the second arm unit 13 and the first arm unit 12.

A regulation surface 11c is provided in the slit 11b as a regulation unit or a regulated unit that regulates predetermined pivoting or more of the second arm unit 13 with respect to the body unit 2 in which the second pivoting axis AX2 is a support point.

By providing the regulation unit or the regulated unit that regulates the predetermined pivoting or more of each unit, it is possible to appropriately prevent scratch due to collision between the respective units. Further, it is easy to maintain an attitude appropriate to each photographic mode to be described below.

### 3. Detection of Pivoting State

In the imaging device 1, a magnet and a magnetic sensor are provided in each unit, and thus it is possible to detect a pivoting state of each of the display unit 4, the first arm unit 12, the second arm unit 13, and the body unit 2.

Specifically, the magnetic sensor performs an output in accordance with a direction or strength (that is, a distance between the magnet and the magnetic sensor) of a magnetic field released from the magnet. That is, when the magnetic sensor outputs an output signal in accordance with a positional relation between the magnetic sensor and the magnet and the output signal is analyzed, each pivoting state can be detected. That is, the pivoting state can be specified with the positional relation between the magnetic sensor and the magnet.

A pivoting state of two members may indicate, for example, the degree of pivoting of two members, may indicate the degree of pivoting of a certain member with respect to the other member, or may indicate an angle formed between the two members. When pivoting is performed using a certain pivoting axis (for example, the first pivoting axis AX1) is a support point, the pivoting state may indicate how much a certain member (for example, the display support unit 5) is pivoted with respect to the other member (for example, the first arm unit 12). The pivoting state may not necessarily indicate a pivoting angle. For example, the pivoting state may indicate a present open state (or a specific open state) between a certain member (the display support unit 5) and the other member (the first arm unit 12) by pivoting or may indicate a relation (or a positional relation) between a certain member (the display support unit 5) and the other member (the first arm unit 12).

In addition to the display support unit 5 and the first arm unit 12, the same goes for the body unit 2 and the second arm unit 13, or the first arm unit 12 and the second arm unit 13.

<3-1. Pivoting State of Display Support Unit and First Arm Unit>

First, a magnet and a magnetic sensor disposed in the display support unit 5 and the first arm unit 12 will be described.

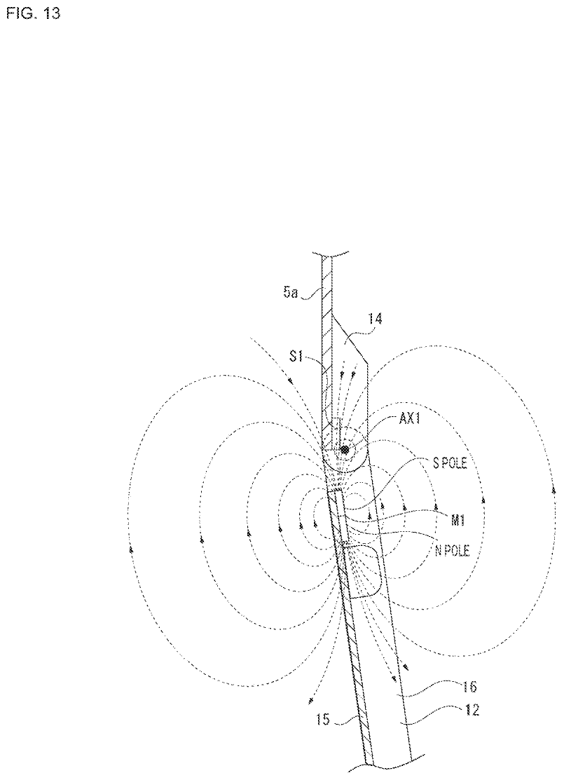

In the embodiment, a first magnet M1 detecting a pivoting state of the display support unit 5 and the first arm unit 12 is provided in the first arm unit 12, and a first magnetic sensor S1 which is influenced by a magnetic field released from the first magnet M1 and outputs a signal is provided in the display support unit 5 (see FIG. 12)

For example, a magnetoresistive element (or a magnetoresistive effect element) is adopted in the first magnetic sensor S1.

Each of FIGS. 12, 13, and 14 is a diagram illustrating the vicinity of the first pivoting axis AX1 as parts of the display support unit 5 and the first arm unit 12.

The N pole and the S pole of the first magnet M1 are continuously disposed in a direction in which the surface of the first base 15 of the first arm unit 12 expands. More specifically, the pole close to the first pivoting axis AX1 is the S pole and the pole distant to the first pivoting axis AX1 is the N pole.

The first magnetic sensor S1 has, for example, a chip shape including a sensor or a wiring and is mounted on a surface opposite to the side on which the display unit 4 is mounted on the plate 5a of the display support unit 5.

The first magnetic sensor S1 outputs a signal indicating either a “detection state” in which a considerable current flows (or a resistant value is small) or a “non-detection state” in which a considerable current does not flow (or a resistance value is large) in accordance with a direction when magnetic flux lines released from the magnet pass through the first magnetic sensor S1.

Specifically, when the resistant value is small and a predetermined current or more flows, a signal indicating the “detection state” is output. When the resistant value is large and the predetermined current or more does not flow, a signal indicating the “non-detection state” is output.

Specifically, the appended drawings are referred to for description.

The state illustrated in FIG. 12 indicates that a pivoting state of the display support unit 5 and the first arm unit 12 is a maximum angle (for example, about 172 degrees). The magnetic flux lines released from the first magnet M1 are represented by dotted lines in the drawing.

In the state illustrated in FIG. 12, the magnetic flux lines near the first magnetic sensor S1 are substantially parallel to the first magnetic sensor S1. Therefore, an output of the first magnetic sensor S1 is the signal indicating the “detection state”.

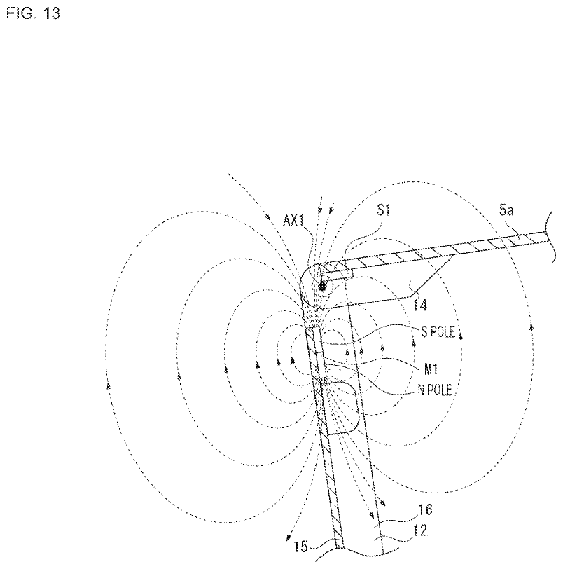

In the state illustrated in FIG. 13, a pivoting state of the display support unit 5 and the first arm unit 12 is about 90 degrees. In the state illustrated in FIG. 13, the magnetic flux lines near the first magnetic sensor S1 are not parallel to the first magnetic sensor S1. Therefore, an output of the first magnetic sensor S1 is the signal indicating the “non-detection state”.

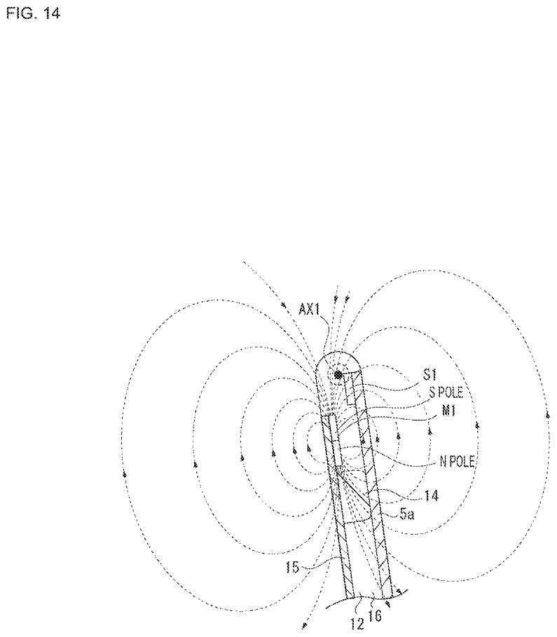

In the state illustrated in FIG. 14, a pivoting state of the display support unit 5 and the first arm unit 12 is the minimum angle (for example, about 0 degrees).

In the state illustrated in FIG. 14, the magnetic flux lines near the first magnetic sensor S1 are not parallel to the first magnetic sensor S1. Therefore, an output of the first magnetic sensor S1 is the signal indicating the “non-detection state”.

In the disposition of the first magnet M1 and the first magnetic sensor S1 according to the embodiment, the output of the first magnetic sensor S1 is the “detection state” only when the pivoting state of the display support unit 5 and the first arm unit 12 is a constant angle or more. In other words, the first magnetic sensor S1 is a sensor that has a function of detecting a state in which the display support unit 5 is pivoted with respect to the first arm unit 12 by the constant angle or more. In the following description, a state in which the output of the first magnetic sensor S1 is in a detection state is referred to as “turning on the first magnetic sensor S1”. Turning on the first magnetic sensor S1 is referred to as “determined as unfolded” and turning off the first magnetic sensor S1 is referred to as “determined as folded” in some cases.

An arrangement direction of the N pole and the S pole of the first magnet M1 preferably matches a direction in which the surface of the first base 15 of the first arm unit 12 which is an installation surface expands. Thus, thinness of the first base 15 in the first magnet M1 in the thickness direction can be achieved.

Further, when the direction of the first magnet M1 is set, as described above, that is, the pole disposed close to the first pivoting axis AX1 is the S pole and the pole disposed away from the first pivoting axis AX1 is the N pole, it is preferable to use a magnetoresistive element so that the first magnetic sensor S1 has the function of detecting a state in which the display support unit 5 is pivoted with respect to the first arm unit 12 by the constant angle or more.

For example, when a Hall element is adopted as the first magnetic sensor 51, the thickness direction of an electronic circuit substrate on which the Hall element is mounted is substantially orthogonal to the thickness direction of the plate 5a.

That is, since the width direction of the electronic circuit substrate is the thickness direction of the plate 5a, it is difficult to cause the thickness of the display support unit 5 to be thin.

On the other hand, when the magnetoresistive element is used as the first magnetic sensor 51, the thickness direction of the electronic circuit substrate is the same as the thickness direction of the plate 5a. Therefore, contribution to the thinness of the display support unit 5 can be achieved.

<3-2. Pivoting State of Body Unit and Second Arm Unit>

Next, a magnet and a magnetic sensor disposed in the body unit 2 and the second arm unit 13 will be described.

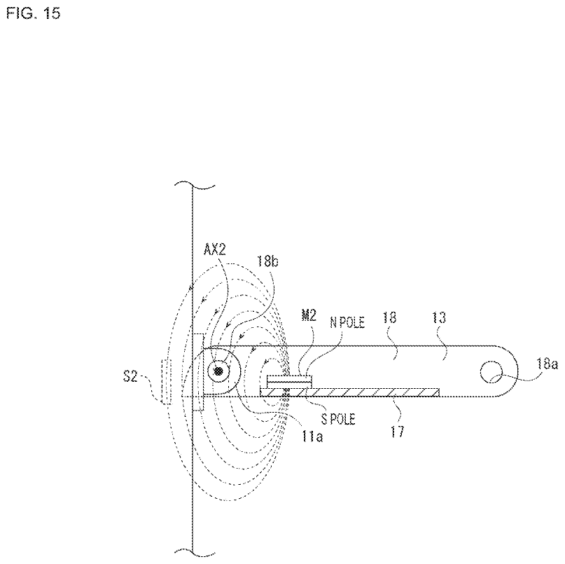

In the embodiment, a second magnet M2 detecting a pivoting state of the body unit 2 (the mounting protrusion 11a) and the second arm unit 13 is provided in the second arm unit 13, and a second magnetic sensor S2 which is influenced by a magnetic field released from the second magnet M2 and outputs a signal is provided in the body unit 2 (see FIG. 15).

For example, a Hall element is adopted in the second magnetic sensor S2.

Each of FIGS. 15, 16, and 17 is a diagram illustrating the vicinity of the second pivoting axis AX2 as parts of the body unit 2 and the second arm unit 13. The S pole and the N pole of the second magnet M2 are continuously disposed in a direction orthogonal to the surface of the second base 17 of the second arm unit 13. More specifically, the surface coming into contact with the second base 17 is the S pole.

The second magnetic sensor S2 has, for example, a chip shape including a sensor or a wiring and is mounted on an electronic circuit substrate disposed inside the body unit 2.

The second magnetic sensor S2 can measure a magnetic flux density of magnetic flux lines released from the magnet. Specifically, a signal in accordance with the density of the magnetic flux lines in the orthogonal direction is output to the element. A signal output of the second magnetic sensor S2 is either a signal indicating a “detection state” in which a predetermined magnetic flux density or more is detected and a signal indicating a “non-detection state” in which the predetermined magnetic flux density or more is not detected.

Specifically, the appended drawings are referred to for description.

The state illustrated in FIG. 15 indicates that a pivoting state of the body unit 2 and the second arm unit 13 is a maximum angle (for example, about 90 degrees). The magnetic flux lines released from the second magnet M2 are represented by dotted lines in the drawing.

In the state illustrated in FIG. 15, the magnetic flux lines near the second magnetic sensor S2 are substantially parallel to the second magnetic sensor S2. Therefore, an output of the second magnetic sensor S2 is the signal indicating the “non-detection state”.

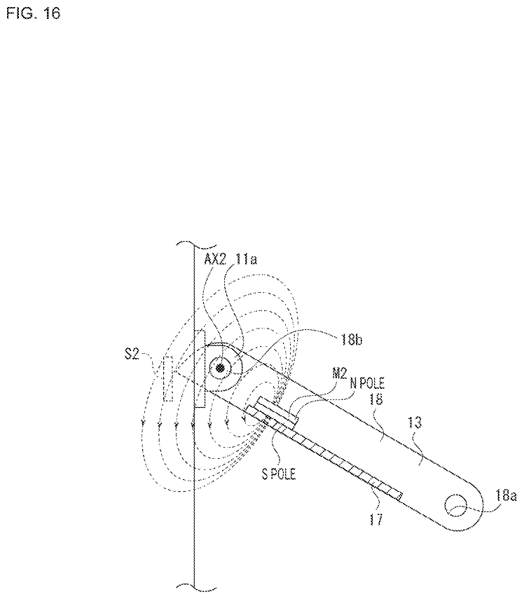

In the state illustrated in FIG. 16, a pivoting state of the body unit 2 and the second arm unit 13 is less than 90 degrees.

In the state illustrated in FIG. 16, the magnetic flux lines near the second magnetic sensor S2 are not perpendicular to the second magnetic sensor S2. Therefore, the detected magnetic flux density is low and an output of the second magnetic sensor S2 is the signal indicating the “non-detection state”.

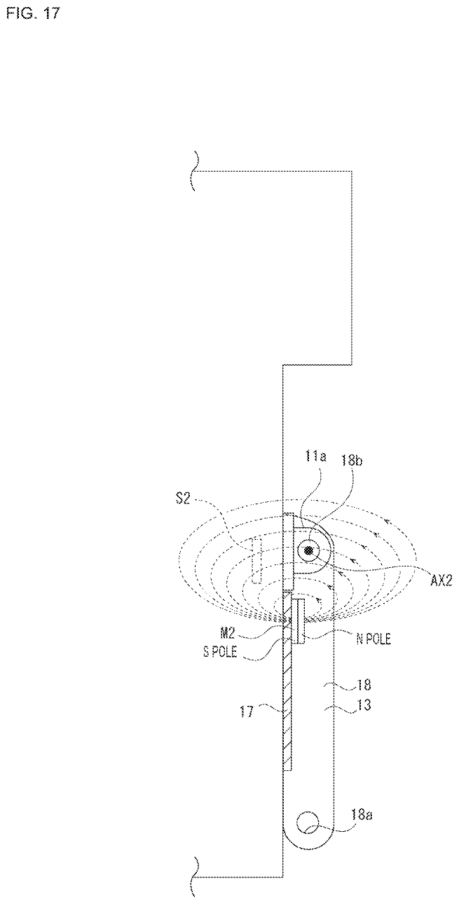

In the state illustrated in FIG. 17, a pivoting state of the body unit 2 and the second arm unit 13 is the minimum angle (for example, about 0 degrees).

In the state illustrated in FIG. 17, the magnetic flux lines near the second magnetic sensor S2 are substantially perpendicular (or nearly perpendicular) to the second magnetic sensor S2. Therefore, the detected magnetic flux density is high and an output of the second magnetic sensor S2 is the signal indicating the “detection state”.

In the disposition of the second magnet M2 and the second magnetic sensor S2 according to the embodiment, the output of the second magnetic sensor S2 is the “detection state” only when the pivoting state of the body unit 2 and the second arm unit 13 is less than a constant angle. In other words, the second magnetic sensor S2 is a sensor that has a function of detecting a state in which the second arm unit 13 is pivoted with respect to the body unit 2 (the mounting protrusion 11a) by an angle of less than constant angle.

In the following description, a state in which the output of the second magnetic sensor S2 is in a detection sate is referred to as “turning on the second magnetic sensor S2”. Turning on the second magnetic sensor S2 is referred to as “determined as folded” and turning off the second magnetic sensor S2 is referred to as “determined as unfolded” in some cases.

<3-3. Pivoting State of Body Unit and Display Support Unit>

Next, a magnet and a magnetic sensor disposed in the body unit 2 and the display support unit 5 will be described.

In the embodiment, a third magnet M3 detecting a pivoting state of the body unit 2 (the housing depression unit 11) and the display support unit 5 is provided in the plate 5a of the display support unit 5, and a third magnetic sensor S3 which is influenced by a magnetic field released from the third magnet M3 and outputs a signal is provided in the body unit 2

For example, a Hall element is adopted in the third magnetic sensor S3.

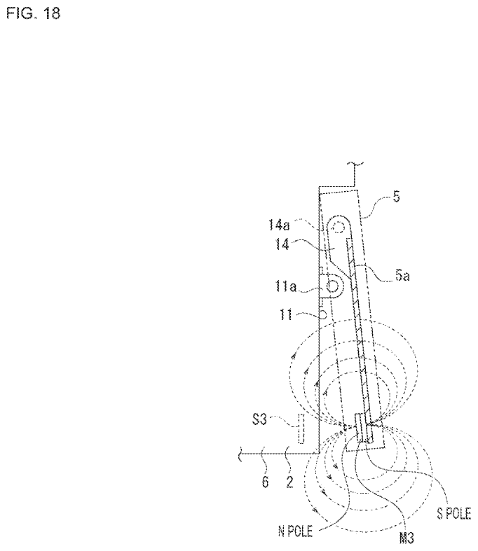

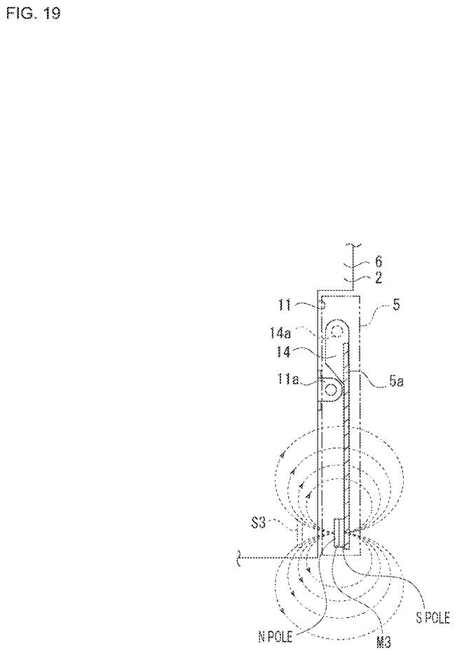

Each of FIGS. 18 and 19 is a diagram illustrating parts of the body unit 2 and the display support unit 5.

The N pole and the S pole of the third magnet M3 are continuously disposed in a direction orthogonal to the surface of the plate 5a. More specifically, the surface coming into contact with the plate 5a is the N pole.

The third magnetic sensor S3 has, for example, a chip shape including a sensor or a wiring and is mounted on an electronic circuit substrate disposed inside the body unit 2.

The third magnetic sensor S3 can measure a magnetic flux density of magnetic flux lines released from the magnet. Specifically, a signal in accordance with the density of the magnetic flux lines in the orthogonal direction is output to the element. A signal output of the third magnetic sensor S3 is either a signal indicating a “detection state” in which a predetermined magnetic flux density or more is detected and a signal indicating a “non-detection state” in which the predetermined magnetic flux density or more is not detected.

Specifically, the appended drawings are referred to for description.

The state illustrated in FIG. 18 is a state in which the display support unit 5 slightly expands from the housing depression unit 11 of the body unit 2 (a separate state). The magnetic flux lines released from the third magnet M3 are represented by dotted lines in the drawing.

In the state illustrated in FIG. 18, the third magnet M3 keeps at a distance from the third magnetic sensor S3. Therefore, the magnetic field near the third magnetic sensor S3 is weak and an output of the third magnetic sensor S3 is the signal indicating the “non-detection state”.

In the state illustrated in FIG. 19, the display support unit 5 is housed in the housing depression unit 11 of the body unit 2.

In the state illustrated in FIG. 19, the distance between the third magnet M3 and the third magnetic sensor S3 is close. Therefore, the magnetic field near the third magnetic sensor S3 is strong and an output of the third magnetic sensor S3 is the signal indicating the “detection state”.

In the disposition of the third magnet M3 and the third magnetic sensor S3 according to the embodiment, the output of the third magnet M3 is in the “detection state” when the pivoting state of the body unit 2 and the display support unit 5 is less than the constant angle. That is, when the body unit 2 and the display support unit 5 approach each other within the constant distance, the output of the third magnetic sensor S3 indicates the “detection state”. In other words, the third magnetic sensor S3 is a sensor that has a function of detecting a state in which the display support unit 5 is housed in the housing depression unit 11 of the body unit 2.

In the following description, a state in which the output of the third magnetic sensor S3 is the detection state is referred to as “turning on the third magnetic sensor S3”. Turning on the third magnetic sensor S3 is referred to as “determined as housed” and turning off the third magnetic sensor S3 is referred to as “determined as not housed determination” in some cases.

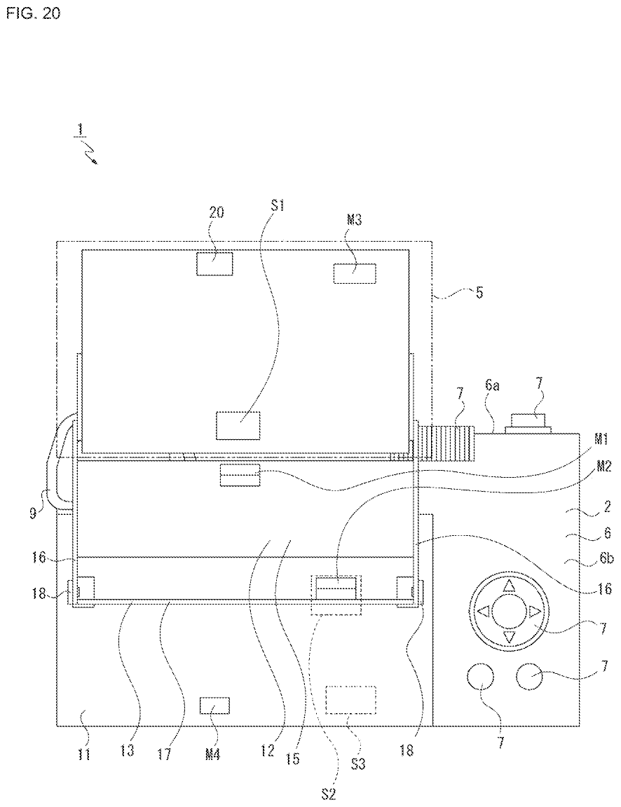

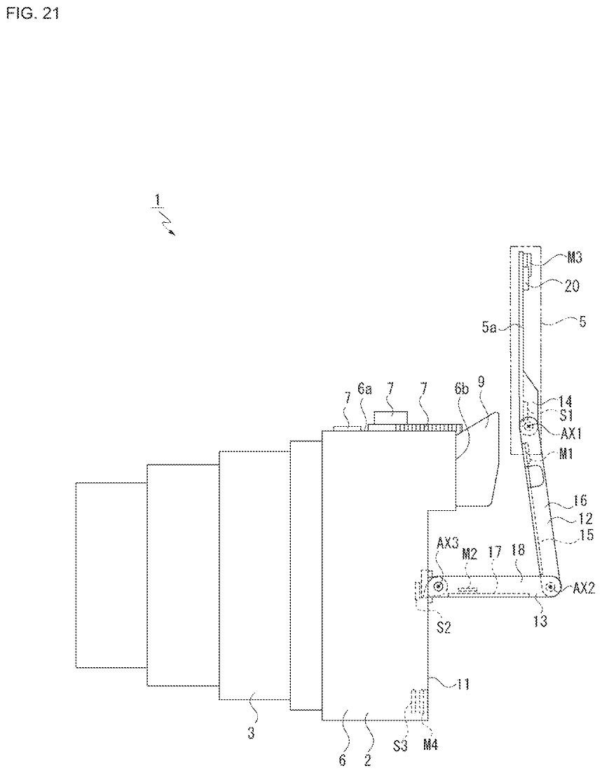

A fourth magnet M4 for maintaining a housed of the display support unit 5 is provided at a position close to the surface of the housing depression unit 11 of the body unit 2 or inside the body unit 2 and close to the surface of the housing depression unit 11. The metal plate 20 is provided at a position corresponding to the fourth magnet M4 in the display support unit 5 (for example, see FIGS. 20 and 21).

When the position of the display support unit 5 with respect to the body unit 2 is moved via the first arm unit 12 and the second arm unit 13 and the distance between the fourth magnet M4 and the metal plate 20 is less than a constant distance, the display support unit 5 is naturally housed in the housing depression unit 11 of the body unit 2 because of a pulling force of the fourth magnet M4 and the metal plate 20.

For example, when an output of the third magnetic sensor S3 is an immediately previous switching state from the “non-detection state” to the “detection state,” the display support unit 5 is naturally housed in the housing depression unit 11, and thus the state in which the display support unit 5 is housed in the housing depression unit 11 can be reliably detected with the output of the third magnetic sensor S3.

Thus, it is possible to appropriately perform display control to be described below or the like.

### 4. Disposition of Magnet and Magnetic Sensor

Disposition of the magnets and the magnetic sensors included in the imaging device 1 will be described with reference to FIGS. 20 and 21.

FIG. 20 is a rear view illustrating the imaging device 1 in the fully unfolded state.

FIG. 21 is a side view illustrating the imaging device 1 in the fully unfolded state.

The first magnetic sensor S1 and the first magnet M1 are provided substantially in the middle of the plate 5a and the first base 15 in the right and left directions (see FIG. 20). Since the first magnetic sensor S1 and the first magnet M1 are located at substantially the same position in the right and left directions, the first magnetic sensor S1 can appropriately detect the magnetic field released from the first magnet M1.

The first magnetic sensor S1 and the first magnet M1 are disposed at positions close to the first pivoting axis AX1 (see FIG. 21).

Specifically, the first magnetic sensor S1 is disposed at a position closer to a fixed end (an end closer to the first pivoting axis AX1 between the ends along the axis direction of the first pivoting axis AX1) than a free end of the plate 5a in the pivoting in which the first pivoting axis AX1 is a support point. The first magnet M1 is disposed at a position closer to the fixed end than the free end of the first base 15 in the pivoting in which the first pivoting axis AX1 is a support point.

Thus, since the first magnetic sensor S1 is disposed near the first magnet M1, a pivoting state of the display support unit 5 and the first arm unit 12 can be detected more accurately.

The fixed end mentioned here is an end on the pivoting axis and the free end is an end opposite to the pivoting axis. That is, the fixed end of the first base 15 in the pivoting in which the first pivoting axis AX1 is a support point is an end of the side connected to the first pivoting axis AX1 (that is, the end close to the first pivoting axis AX1) and the free end of the first base 15 in the pivoting in which the first pivoting axis AX1 is a support point is the end distant from the first pivoting axis AX1.

The second magnetic sensor S2 and the second magnet M2 are disposed on the right side in the right and left directions of the second base 17 and the housing depression unit 11 of the body unit 2. Since the second magnetic sensor S2 and the second magnet M2 are located at substantially the same position in the right and left directions, the second magnetic sensor S2 can appropriately detect the magnetic field released from the second magnet M2.

The second magnetic sensor S2 and the second magnet M2 are disposed to be separate at least in the right and left directions with respect to the first magnetic sensor S1 and the first magnet M1 (see FIG. 20). Thus, it is possible to prevent the first magnetic sensor S1 from being strongly influenced by the magnetic field released from the second magnet M2 or prevent the second magnetic sensor S2 from being strongly influenced by the magnetic field released from the first magnet M1.

The second magnetic sensor S2 and the second magnet M2 are disposed at positions closes to the second pivoting axis AX2 (see FIG. 21).

Specifically, the second magnetic sensor S2 is disposed at a position close to the housing depression unit 11 of the body unit 2. The second magnet M2 is disposed at a position closer to the fixed end than the free end of the second base 17 in the pivoting in which the second pivoting axis AX2 is a support point.

Thus, since the second magnetic sensor S2 is disposed near the second magnet M2, a pivoting state of the body unit 2 and the second arm unit 13 can be detected more accurately.

The fixed end mentioned here is an end on the pivoting axis and the free end is an end opposite to the pivoting axis. That is, the fixed end of the second base 17 in the pivoting in which the second pivoting axis AX2 is a support point is an end of the side connected to the second pivoting axis AX2 (that is, the end close to the second pivoting axis AX2) and the free end of the second base 17 in the pivoting in which the second pivoting axis AX2 is a support point is the end distant from the second pivoting axis AX2.

Further, the second magnetic sensor S2 and the second magnet M2 are disposed to be separate in the top and bottom directions in a state in which the second arm unit 13 is housed in the housing depression unit 11, as illustrated in FIG. 17. Thus, since the second magnetic sensor S2 and the second magnet M2 are not superimposed in the front and rear directions, that is, the thickness direction of the imaging device 1, in the housed, thinness of the imaging device 1 can be achieved.

The third magnetic sensor S3 and the third magnet M3 are disposed on the right side in the right and left directions of the body unit 2 and the plate 5a (see FIG. 20). Since the third magnetic sensor S3 and the third magnet M3 are located at substantially the same position in the right and left directions, the third magnetic sensor S3 can appropriately detect the magnetic field released from the third magnet M3.

The third magnetic sensor S3 and the third magnet M3 are disposed to be separate at least in the right and left directions with respect to the first magnetic sensor S1 and the first magnet M1 (see FIG. 21). Thus, it is possible to prevent the first magnetic sensor S1 from being strongly influenced by the magnetic field released from the third magnet M3 or prevent the third magnetic sensor S3 from being strongly influenced by the magnetic field released from the first magnet M1.

Further, the third magnetic sensor S3 is located below the second magnet M2 (see FIG. 21). That is, the third magnetic sensor S3 and the second magnet M2 is disposed to be separate up and down. Thus, it is possible to prevent the third magnetic sensor S3 from being strongly influenced by the magnetic field released from the second magnet M2.

Further, the third magnet M3 is disposed at the end distant from the first pivoting axis AX1 between the ends of the plate 5a in the axis direction of the first pivoting axis AX1.

That is, in a state in which the display support unit 5 is pivoted so that an angle formed between the display support unit 5 and the first arm unit 12 becomes 0 degrees (that is, the state illustrated in FIG. 4), the third magnet M3 is located close to the third pivoting axis AX3. Since the second magnetic sensor S2 is located close to the second pivoting axis AX2, the third magnet M3 and the second magnetic sensor S2 are disposed to be separate in any pivoting state. Thus, the second magnetic sensor S2 is prevented from being strongly influenced by the magnetic field released from the third magnet M3.

The fourth magnet M4 is provided substantially in the middle of a bottom end of the housing depression unit in the right and left directions (see FIG. 20). The fourth magnet M4 is disposed to be separate below the first magnetic sensor S1 and the second magnetic sensor S2. The fourth magnet M4 and the third magnetic sensor S3 are disposed to be separate in the right and left directions.

Thus, the first magnetic sensor S1, the second magnetic sensor S2, and the third magnetic sensor S3 are prevented from being strongly influenced by the magnetic field released from the fourth magnet M4.

In the fully housed state, the fourth magnet M4 and the metal plate 20 are located at positions away from the second pivoting axis AX2 as much as possible, and thus the magnetic force for maintaining a housed of the display support unit 5 is small. That is, a magnet that has a weakest magnetic force can be adopted as the fourth magnet M4. Thus, it is possible to exclude a possibility of the magnetic field released from the fourth magnet M4 having an influence on the first magnetic sensor S1, the second magnetic sensor S2, and the third magnetic sensor S3. Further, the fourth magnet M4 and the metal plate 20 are provided substantially in the middle in the right and left direction, and thus a satisfactory housed of the display support unit 5 can be guaranteed. Thus, it is possible to prevent one end of the display support unit 5 in the maintained state in the right and left directions from floating.

As illustrated in FIGS. 20 and 21, the magnet and magnetic sensor corresponding to each other are disposed at close positions in accordance with each pivoting state, and thus it is possible to appropriately measure the pivoting state of each unit. The magnet and magnetic sensor not corresponding to each other are disposed at separate positions irrespective of the pivoting state of each unit, and thus it is possible to exclude a possibility of erroneous determination of the pivoting state of each unit.

Of the first magnetic sensor S1, the second magnetic sensor S2, and the third magnetic sensor S3, the magnetic sensors disposed in the body unit 2 are only the second magnetic sensor S2 and the third magnetic sensor S3. That is, the second magnetic sensor S2 and the third magnetic sensor S3 can be supplied with power by a wiring disposed inside the body unit 2, an electronic circuit substrate, or the like. However, since the first magnetic sensor S1 is disposed in a portion other than the body unit 2, that is, the display support unit 5, it is necessary to extend and connect a wiring from the body unit 2.

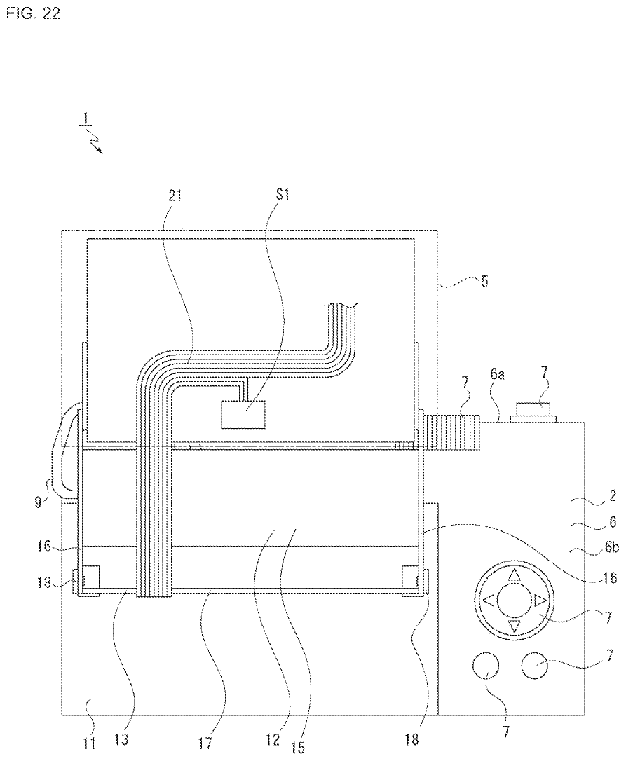

In this example, the flexible substrate 21 wired for another member is used. Specifically, FIG. 22 is referred to for description.

The display unit 4 is mounted in the display support unit 5, and the display unit 4 and the electronic circuit substrate disposed inside the body unit 2 are electrically connected by the flexible substrate 21. Thus, it is possible to control display of a captured image or the like on the display unit 4.

The flexible substrate 21 connecting the display unit 4 to the electronic circuit substrate in the body unit 2 is disposed along the first arm unit 12 and the second arm unit 13. As illustrated in FIG. 22, the flexible substrate 21 extending from the inside to the outside of the body unit 2 is disposed along the bottom surface of the second arm unit 13, the rear surface of the first arm unit 12, and the rear surface of the plate 5a in the fully unfolded state.

In the embodiment, a portion disposed on the rear surface of the plate 5a in the flexible substrate 21 is branched toward the first magnetic sensor S1, and supply of power to the first magnetic sensor S1 or transmission and reception of a signal are performed.

In a certain portion (that is a branched portion) connecting the flexible substrate 21 to the first magnetic sensor S1, the number of wirings is small. The portion is thinner than another portion of the flexible substrate 21. Thus, a concern about disconnection or the like is higher than that of another portion. By determining the disposition of the flexible substrate 21 and the first magnetic sensor S1 so that the distance between the flexible substrate 21 and the first magnetic sensor S1 is as short as possible, it is possible to reduce the concern about the disconnection.

The flexible substrate 21 and the magnetic sensor S1 are mounted together in the plate 5a, and thus the branched portion cannot be bent or twisted even during the pivoting of the display support unit 5 with respect to the first arm unit 12. Thus, disconnection of the branched portion is difficult.

Further, the length of the branched portion is short, and thus it is easy to process wirings.

The second magnetic sensor S2 and the third magnetic sensor S3 disposed in the body unit 2 may be connected to one flexible substrate (not illustrated). Thus, since the number of components can be further reduced than in the case in a flexible substrate for the second magnetic sensor S2 and a flexible substrate for the third magnetic sensor S3 are separately provided, contribution to a reduction in cost can be achieved.

A dedicated flexible substrate for the magnetic sensors may be provided or a flexible substrate provided for the various operational units 7 (that is, buttons or the like) disposed in the body unit 2 may be used. When the second magnetic sensor S2 and the third magnetic sensor S3 are connected to the flexible substrate provided for the operational units 7, it is not necessary to prepare for a dedicated flexible substrate for the second magnetic sensor S2 and the third magnetic sensor S3. Thus, it is possible to achieve a reduction in the number of components.

By connecting the flexible substrate 21 to the second magnetic sensor S2 and the third magnetic sensor S3, a substrate connected to the three magnetics sensors may be commonly used. Thus, it is possible to further reduce the number of components.

### 5. Control Configuration of Imaging Device

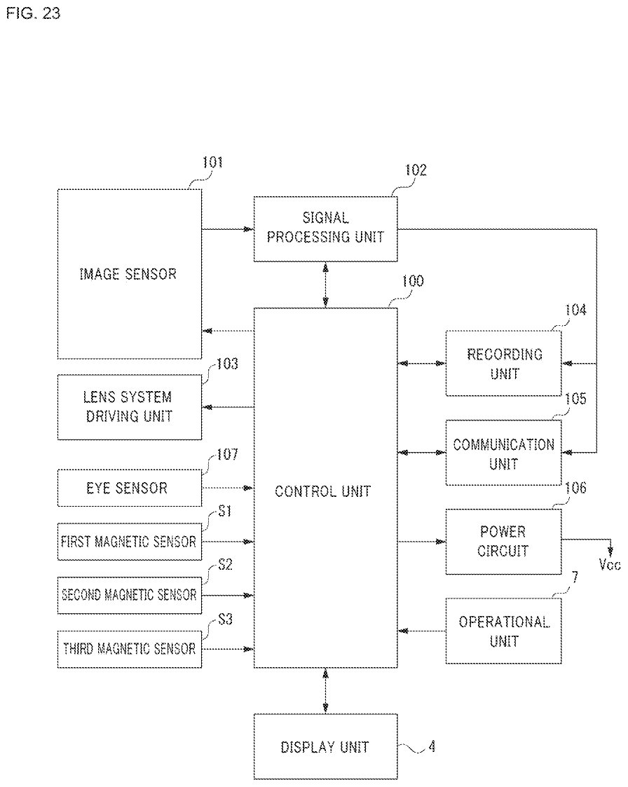

In the imaging device 1, a photographic mode is automatically determined in accordance with a combination of signals output by the above-described magnetic sensors, and various kinds of control is performed. First, a control configuration of the imaging device 1 will be described with reference to FIG. 23.

The body unit 2 of the imaging device 1 includes a control unit 100, an image sensor 101, a signal processing unit 102, a lens system driving unit 103, a recording unit 104, a communication unit 105, a power circuit 106, and an eye sensor 107. In addition, the above-described operational units 7 are provided in the body unit 2. As described above, the imaging device 1 includes the display unit 4, the first magnetic sensor S1, the second magnetic sensor S2, and the third magnetic sensor S3.

The image sensor 101 includes, for example, an imaging element in which photoelectric conversion pixels are disposed and formed in a matrix form, such as a type of charge coupled device (CCD) or a type of complementary metal oxide semiconductor (CMOS). For the image sensor 101, light from a subject is condensed on the image sensor 101 by an optical system (not illustrated). The optical system is, for example, lenses such as a cover lens, a zoom lens, and a focus lens, a diaphragm mechanism, an optical filter, and the like, which are disposed appropriately inside a lens barrel or inside and outside of the casing 6.

The image sensor 101 performs, for example, a corrected double sampling (CDS) process, an automatic gain control (AGC) process, and the like on an electrical signal obtained through photoelectric conversion in the imaging element and further performs an analog/digital (A/D) conversion process. A captured image signal is output as digital data to the signal processing unit 102. The image sensor 101 outputs an image signal as, for example, so-called raw data.

The signal processing unit 102 is configured as, for example, a processor such as a digital signal processor (DSP) for image processing. The signal processing unit 102 performs various kinds of signal processing on the captured image signal from the image sensor 101.

For example, the signal processing unit 102 performs a clamping process of clamping a black level of R, G, and B to a predetermined level, a correction process between color channels of R, G, and B, demosaic processing performed so that image data of pixels have all color components of R, G, and B, and process of generating (separating) a luminance signal and a color signal, and the like.

Further, the signal processing unit 102 performs a necessary resolution conversion process, for example, resolution conversion for recording, communication output, or the display unit 4, on the image data obtained through the various kinds of signal processing.

Furthermore, the signal processing unit 102 performs, for example, a compression process, an encoding process, or the like for recording or communication output on the image data obtained through the resolution conversion.

The signal processing unit 102 may perform a process of generating a monitor image signal for displaying a through image and supply the monitor image signal to the display unit 4, an output terminal, or the like.

The lens system driving unit 103 drives the focus lens, the zoom lens, the diaphragm mechanism, an optical filter mechanism, and the like of the foregoing optical system under the control of the control unit 100.

The recording unit 104 is realized by, for example, a nonvolatile memory and functions as a storage region for storing still image data, moving image data, attribution information of an image file, a thumbnail image, and the like. Various forms of the recording unit 104 can be considered. For example, the recording unit 104 may be a flash memory embedded in the body unit 2 or may be a form of a memory card (for example, a portable flash memory) detachably mounted in the body unit 2 for use and a card recording reproduction unit that performs recording, reproducing, accessing on the memory card. The recording unit 104 may be realized by a hard disk drive (HDD) embedded in the body unit 2. A captured image displayed on the display unit 4 may be a through image based on a captured image signal obtained through an A/D conversion process or may be image data (still image data or moving image data) stored in the recording unit 104. For example, the control unit 100 performs processes of outputting a signal generated by the signal processing unit 102 to the recording unit 104 and displaying image data recorded on the recording unit 104 to the display unit 4.

The communication unit 105 performs data communication or network communication with an external device in a wired or wireless manner. For example, the captured image data is transmitted to and received from an external display device, a recording device, a reproducing device, or the like. As the network communication unit, for example, communication may be performed via the Internet to transmit and receive various kinds of data to and from a server, a terminal, or the like on a network.

The power circuit 106 generates a necessary power voltage (Vcc) using, for example, a battery as a power source and supplies the power voltage to each unit of the body unit 2.

The power circuit 106 supplies a necessary driving voltage to the display unit 4.

The eye sensor 107 is a sensor that outputs a signal for determining whether a photographer peers into the finder window 8 and is provided near the finder window 8. The eye sensor 107 is considered as, for example, a proximity sensor or the like.

The control unit 100 is configured by a microcomputer (an arithmetic processing device) that includes a central processing unit (CPU), a read-only memory (ROM), a random access memory (RAM), and a flash memory.

The CPU generally controls the entire imaging device 1 by executing a program stored in the ROM, the flash memory, or the like.

The RAM is used as a working area to temporarily store data, a program, or the like when the CPU processes various kinds of data.

The ROM or the flash memory (a nonvolatile memory) is used to store application programs, firmware, and the like for various operations in addition to a content file such as an image file or an operating system (OS) for causing the CPU to control each unit.

The control unit 100 controls a necessary operation of each unit such as parameter control of various kinds of signal processing in the signal processing unit 102, an imaging operation or a recording operation in response to an operation of a photographer or the like, a reproducing operation for a recorded image file, an imaging operation of the image sensor 101, camera operations such as zooming, focusing, and exposure adjustment, and a user interface operation. Therefore, the control unit 100 transmits a control signal to the image sensor 101 or the lens system driving unit 103. For example, the control unit 100 outputs a control signal or a clock signal for a shutter speed, a frame rate, or the like in the image sensor 101 or a control signal for the lens system driving unit 103.

The control unit 100 outputs a control signal for driving each unit based on operations such as a power button, a shutter button, a mode switching knob, and the like on the various operational units 7.

The control unit 100 acquires various signals output from the eye sensor 107, the first magnetic sensor S1, the second magnetic sensor S2, and the third magnetic sensor S3 and performs, for example, display control of a captured image or an icon image displayed on the display unit 4 based on the signals.

When the display unit 4 has a touch panel function, operational information of an operator on the display unit 4 is acquired from the display unit 4 and control of each unit based on the operational information is performed.

The control unit 100 may acquire signals indicating determination results from the first magnetic sensor S1, the second magnetic sensor S2, and the third magnetic sensor S3 or may acquire values such as voltage values, current values, or resistant values for estimating the pivoting states.

When the signal indicating the determination result is acquired, each magnetic sensor outputs, for example, 0 (LOW) or 1 (HI) as a signal indicating whether the detected magnetic flux density is equal to or greater than a predetermined value. For example, when the magnetic flux density detected by the magnetic sensor is less than the predetermined value, 0 (LOW) is output. When the magnetic flux density detected by the magnetic sensor is equal to or greater than the predetermined value, 1 (HI) is output. The fact that the output of the magnetic sensor is 0 (LOW) is referred to as a state in which the magnetic sensor is turned off. Similarly, the fact that the output of the magnetic sensor is 1 (HI) is referred to as a state in which the magnetic sensor is turned on.

When the voltage value, the current value, or the resistant value for estimating the pivoting state is acquired, each magnetic sensor outputs a signal indicating a voltage value or the like changed in accordance with the detected magnetic flux density. Accordingly, based on the signal, the control unit 100 determines whether an angle between two members is equal to or greater than a predetermined angle. For example, when the voltage value or the like acquired from the magnetic sensor is equal to or greater than a predetermined voltage, the control unit 100 determines 1 (HI: a detection state). When the voltage or the like is less than the predetermined voltage, the control unit 100 determines 0 (LOW: a non-detection state). When the control unit 100 determines 1 (HI), it is indicated that the corresponding magnetic sensor is turned on. When the control unit 100 determines 0 (LOW), it is indicated that the corresponding magnetic sensor is turned off.

### 6. Relation Between Photographic Mode and Detection State of Each Magnetic Sensor

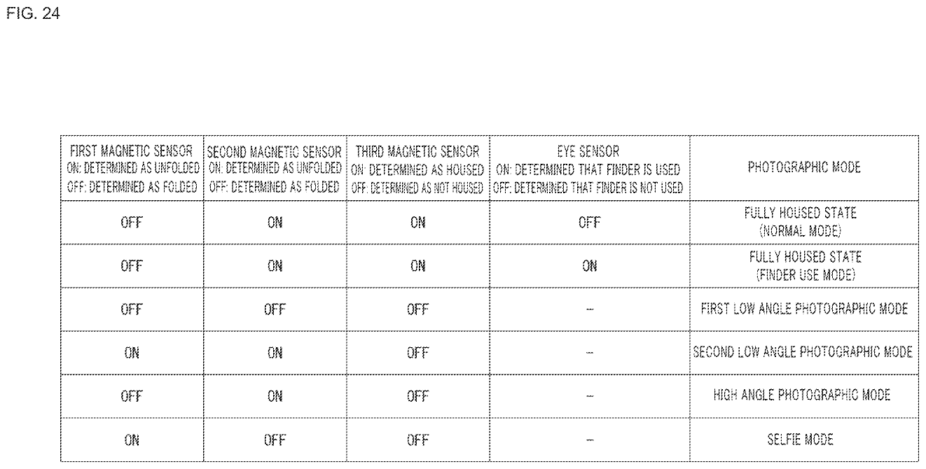

A relation between a signal output by each sensor and a photographic mode will be described with reference to FIG. 24.

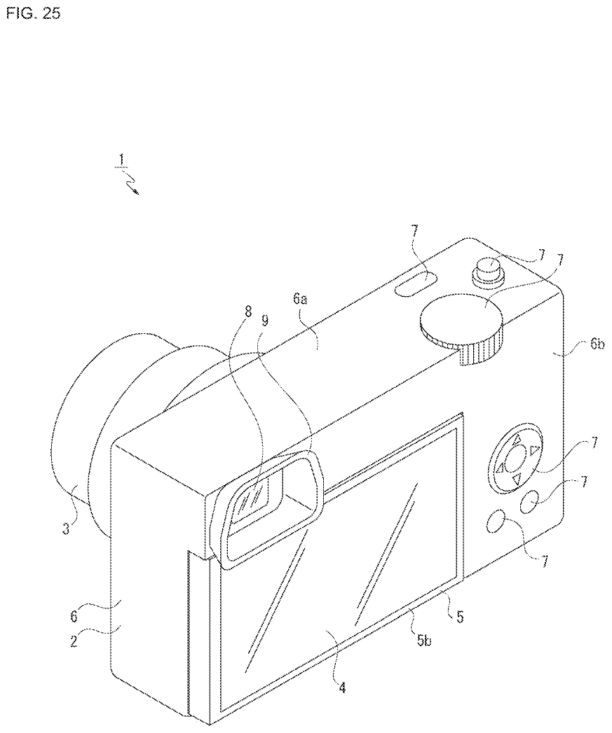

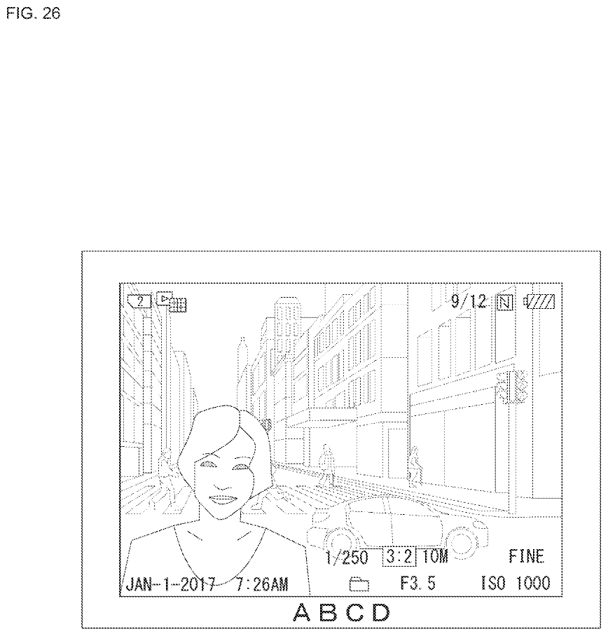

A state in which the first magnetic sensor S1 is turned off (determined as folded), the second magnetic sensor S2 is turned on (determined as folded), and the third magnetic sensor S3 is turned on (determined as housed) is the fully housed state (see FIGS. 10 and 25). Since this state is a state in which the display surface of the display unit 4 is wished on the rear surface, it is considered that a subject in front is imaged at a general posture. Therefore, an image displayed on the display surface of the display unit 4 when viewed from the rear side of the imaging device 1 is, for example, in the state illustrated in FIG. 26. That is, the top and bottom directions of the display unit 4 matches the top and bottom directions of the displayed image. The top and bottom directions of a text notation in each icon image or image displayed on the display surface are also the same as the top and bottom directions of the display unit 4.

When it is detected that the third magnetic sensor S3 is turned on (determined as housed), the fully housed state may be determined irrespective of signals acquired from the first magnetic sensor S1 and the second magnetic sensor S2.

When the imaging device 1 includes the eye sensor 107, display of an image on the display unit 4 may be switched between ON and OFF based on a signal output from the eye sensor 107. For example, when the eye sensor 107 is turned off, that is, the photographer does not peer through a finder, display of an image on the display unit 4 is performed. When the eye sensor 107 is turned on, that is, the photographer peers through the finder, the display of the image on the display unit 4 may be stopped. Thus, contribution to a reduction in power consumption can be achieved. Since the display unit 4 can also be prevented from being heated, a failure or the like can be prevented.

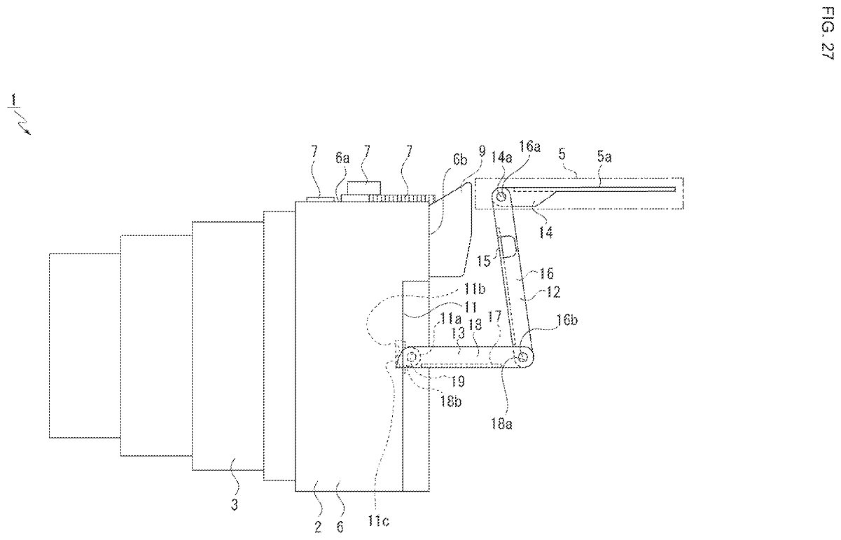

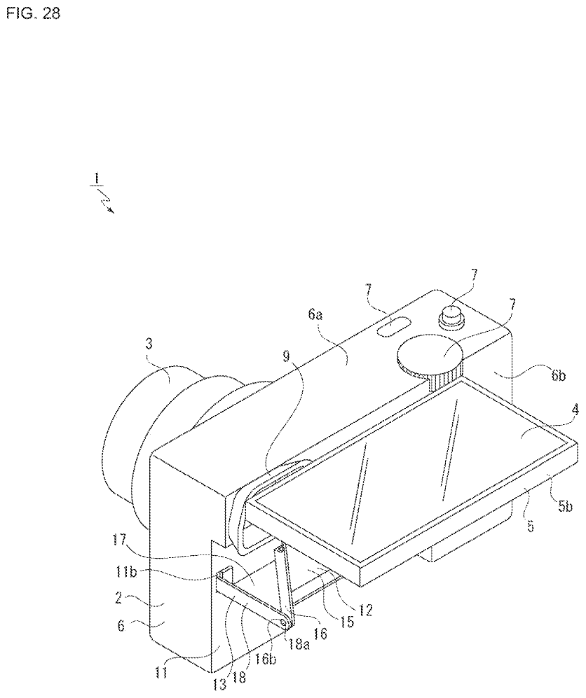

A state in which the first magnetic sensor S1 is turned off (determined as folded), the second magnetic sensor S2 is turned off (determined as unfolded), and the third magnetic sensor S3 is turned off (determined as not housed) is the first low angle photographic mode (see FIGS. 27 and 28). Since this state is a state in which the display surface of the display unit 4 is oriented substantially upwards, this state is easily used when the subject is imaged from the bottom side.

The pivoting state of the display support unit 5 with respect to the first arm unit 12 can also be smaller than the state illustrated in FIGS. 27 and 28 so that the display surface of the display unit 4 is appropriate for the diagonal upward back. The image displayed on the display surface of the display unit 4 is, for example, the state illustrated in FIG. 26.

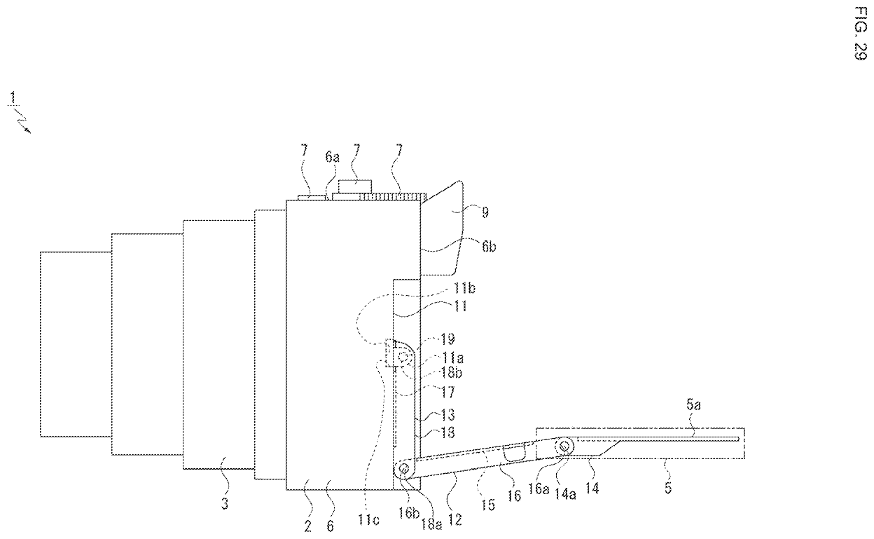

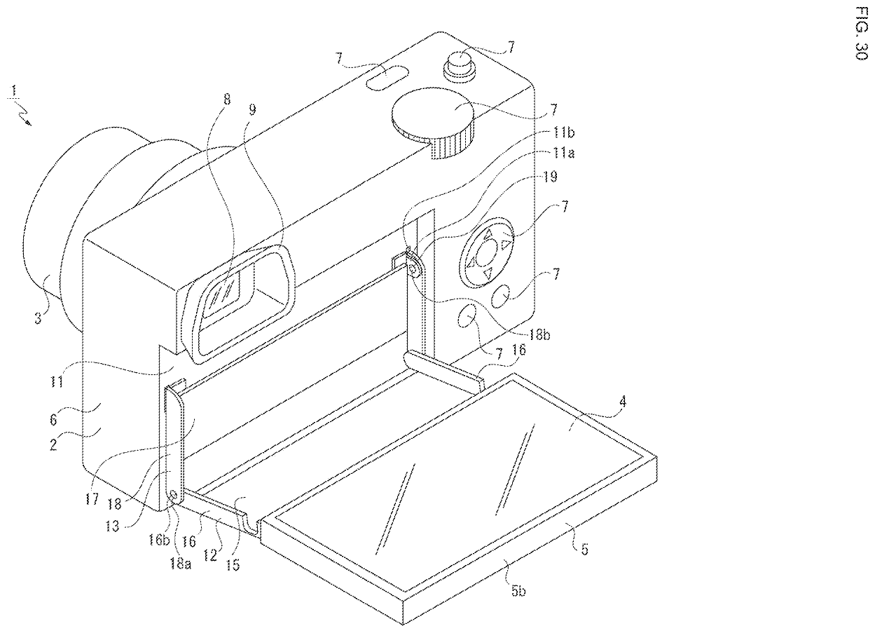

A state in which the first magnetic sensor S1 is turned on (determined as unfolded), the second magnetic sensor S2 is turned on (determined as folded), and the third magnetic sensor S3 is turned off (determined as not housed) is the second low angle photographic mode (see FIGS. 29 and 30).

Since this state is a state in which the display surface of the display unit 4 is oriented substantially upwards, this state is easily used when the subject is imaged from the bottom side like the first low angle photographic mode. The image displayed on the display surface of the display unit 4 is, for example, the state illustrated in FIG. 26.

When the eye sensor 107 is provided in the imaging device 1 and an electronic viewfinder (EVF) is further included in the finder and the photographic mode of the first low angle photographic mode (see FIG. 27) is selected, there is a concern of the photographer being erroneously determined to peer through the finder due to the position of the first arm unit 12. In this case, the display of the display unit 4 may be stopped and display of a through image to the EVF may be started. In this configuration, however, by appropriately determining that the third magnetic sensor S3 is turned off (determined as not housed), the first low angle photographic mode is appropriately determined, and thus the display of the display unit 4 is not stopped. Thus, the photographer can perform imaging appropriate for the photographic mode. Power consumption arising due to display of a through image to the EVF which is not used is suppressed.

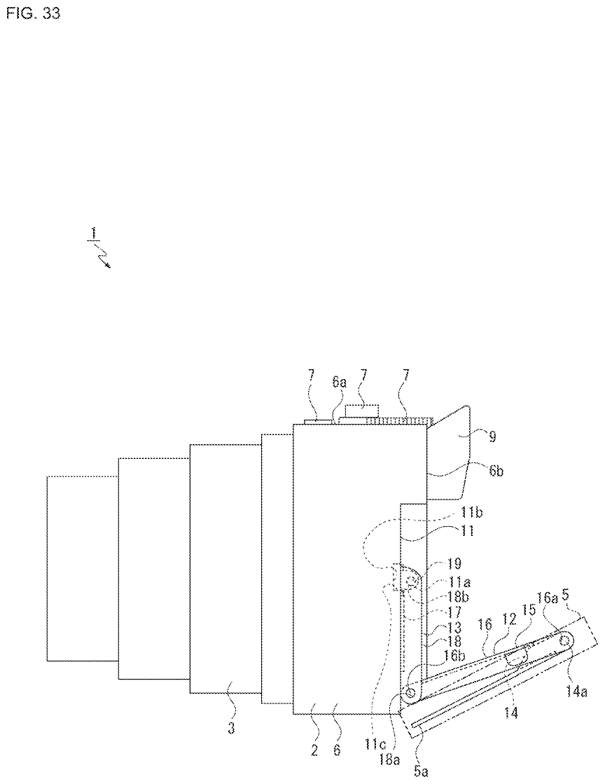

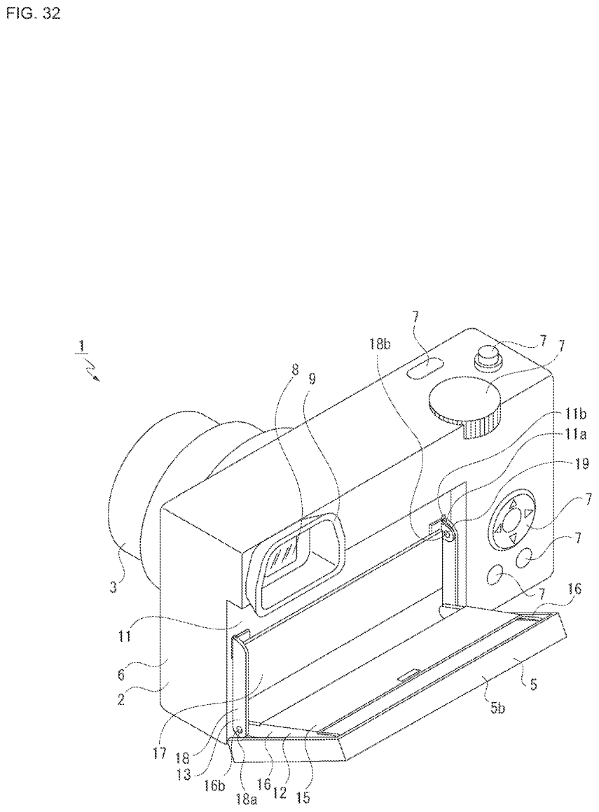

A state in which the first magnetic sensor S1 is turned off (determined as folded), the second magnetic sensor S2 is turned on (determined as folded), and the third magnetic sensor S3 is turned off (determined as not housed) is the high angle photographic mode (see FIGS. 31 and 32).

Since this state is a state in which the display surface of the display unit 4 is oriented to the diagonal downward back, this state is easily used when the subject is imaged from the top side. The image displayed on the display surface of the display unit 4 is, for example, the state illustrated in FIG. 26.

A state in which the first magnetic sensor S1 is turned on (determined as unfolded), the second magnetic sensor S2 is turned off (determined as unfolded), and the third magnetic sensor S3 is turned off (determined as not housed) is the selfie mode (see FIGS. 2 and 11).

This state is a state in which the display unit 4 is located above the body unit 2 and the display surface is oriented forwards. That is, this state is a mode in which a captured image displayed on the display surface can be checked from the subject side, for example, a mode appropriate for selfie.

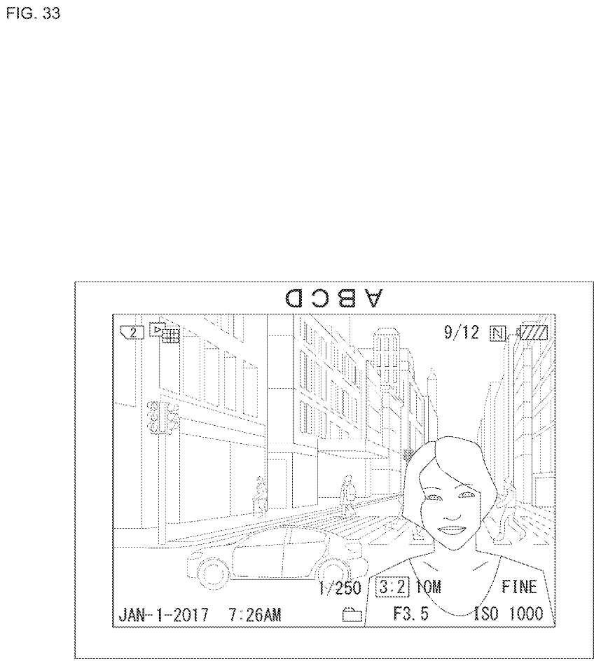

An image displayed on the display surface of the display unit 4 in the selfie mode is, for example, in a state illustrated in FIG. 33. The state illustrated in FIG. 33 shows the display unit 4 viewed from the front side of the imaging device 1. That is, a captured image turned upside down is displayed on the display unit 4. That is, a display image of which the top and bottom directions are not reversed and only the right and left directions are reversed is displayed on the display unit 4 which is turned upside down and is in the state illustrated in FIG. 33.

Text display in each icon image or image is also similarly turned upside down on the display unit 4 so that only the right and left directions of the text are reversely disposed and displayed with respect to the display unit 4 which is in the upside-down state.

In each photographic mode of the first low angle photographic mode, the second low angle photographic mode, the high angle photographic mode, and the selfie mode, the display control of the display unit 4 may be performed based on a signal output from the eye sensor 107. For example, when the signal output from the eye sensor 107 is turned on, the display of the display unit 4 may be stopped.

### 7. Conclusion

The imaging device 1 according to the present technology includes: the display support unit 5 configured to support the display unit 4 that displays an image captured by the body unit 2; the first arm unit 12 of which one end is connected to the display support unit 5; the first magnet M1 provided in one of the display support unit 5 and the first arm unit 12; and the first magnetic sensor S1 provided in the other of the display support unit 5 and the first arm unit 12. The pivoting state of the display support unit 5 and the first arm unit 12 is variable using the first pivoting axis AX1 as a support point. The first magnetic sensor S1 receives a magnetic field released from the first magnet M1 and outputs a signal in accordance with the pivoting state of the display support unit 5 and the first arm unit 12. The pivoting state of the display support unit 5 and the first arm unit 12 may be, for example, the degree of pivoting of the first arm unit 12 with respect to the display support unit 5, may be the degree of pivoting of the display support unit 5 with respect to the first arm unit 12, or may be an angle formed between the display support unit 5 and the first arm unit 12. When the pivoting is performed using the first pivoting axis AX1 as a support point (a support point axis), the pivoting state may indicate how much the display support unit 5 and the first arm unit 12 are pivoted. The pivoting state may not necessarily indicate a pivoting angle. For example, the pivoting state may indicate how much the first arm unit 12 and the display support unit 5 are presently opened (or a specific degree of opening) or may indicate a relation (or a positional relation) between the first arm unit 12 and the display support unit 5.

When a signal indicating the pivoting state of the first arm unit 12 and the display support unit 5 supporting the display unit 4 is output from the first magnetic sensor S1, the pivoting state of the display unit 4 and the first arm unit 12 can be measured. The signal in accordance with the pivoting state of the display unit 4 with respect to the body unit 2 can be acquired and appropriate image control or the like can be performed in accordance with a shooting posture (that is, a photographic mode) of the user.

Further, when the first magnet M1 and the first magnetic sensor S1 corresponding thereto are used for the pivoting state, a mechanism detecting the pivoting state can be miniaturized. Furthermore, contribution to miniaturization of the imaging device 1 can be achieved.

The above-described imaging device 1 may include the second arm unit 13 of which one end is connected to the body unit 2; the second magnet M2 provided in one of the body unit 2 and the second arm unit 13; and the second magnetic sensor S2 provided in the other of the body unit 2 and the second arm unit 13. A pivoting state of the body unit 2 and the second arm unit 13 is variable using the second pivoting axis AX2 as a support point (a support point axis). The second magnetic sensor S2 receives a magnetic field released from the second magnet M2 and outputs a signal in accordance with the pivoting state of the body unit 2 and the second arm unit 13.

The pivoting state of the body unit 2 and the second arm unit 13 may indicate, for example, the degree of pivoting of the second arm unit 13 with respect to the body unit 2, may be the degree of pivoting of the body unit 2 with respect to the second arm unit 13, or may indicate an angle formed between the body unit 2 and the second arm unit 13.

When a signal indicating the pivoting state of the body unit 2 and the second arm unit 13 is output, the pivoting state of the body unit 2 and the second arm unit 13 can be measured. The imaging device 1 has the pivoting axis on which the display support unit 5 is pivoted with respect to the first arm unit 12 (the first pivoting axis AX1), the pivoting axis on which the second arm unit 13 is pivoted with respect to the body unit 2 (the second pivoting axis AX2), and the pivoting axis on which the first arm unit 12 is pivoted with respect to the second arm unit 13 (the third pivoting axis AX3), and thus the attitude of the display support unit 5 can be changed minutely. Since the attitude of the display unit 4 can be changed using the three axes, it is possible to switch various photographic modes such as the selfie mode, the low-angle photographic mode, and the high-angle photographic mode with high accuracy.

Further, in the imaging device 1 in which the attitude of the display unit can be changed using the three axes, the pivoting state can be detected using the first and second magnets (M1 and M2) and the first and second magnetic sensors (S1 and S2), and thus the mechanism detecting the pivoting state can be miniaturized.

In the above-described imaging device 1, the other end which is opposite to the one end of the second arm unit 13 may be connected to the other end which is opposite to the one end of the first arm unit 12.

That is, the display support unit 5 can be pivoted with respect to the body unit 2 via the first arm unit 12 and the second arm unit 13. Thus, in accordance with the photographic mode, the display support unit 5 can be moved to an appropriate position with respect to the body unit 2.

In the above-described imaging device 1, the first magnetic sensor S1 may output a signal in accordance with a positional relation between the first magnetic sensor S1 and the first magnet M1 changing with a change in the pivoting state of the display support unit 5 and the first arm unit 12.

When the signal in accordance with the change in the pivoting state of the display support unit 5 and the first arm unit 12 is output, the positional relation between the display support unit 5 and the first arm unit 12 can be detected. Accordingly, the appropriate display control can be performed in accordance with the direction or the position of the display unit 4 or the shooting posture of the user.

In the above-described imaging device 1, the second magnetic sensor S2 may output a signal in accordance with a positional relation between the second magnetic sensor S2 and the second magnet M2 changing with a change in the pivoting state of the body unit 2 and the second arm unit 13.

When the signal in accordance with the change in the pivoting state of the body unit 2 and the second arm unit 13 is output, the positional relation between the body unit 2 and the second arm unit 13 can be detected. Accordingly, appropriate display control can be performed in accordance with the direction or the position of the display unit 4 or the shooting posture of the user.

In the above-described imaging device 1, the first magnetic sensor S1 may be provided in the display support unit 5 and the first magnet M1 is provided in the first arm unit 12.

Compared to the case in which the first magnetic sensor S1 is provided in the first arm unit 12, thinness of the first arm unit 12 can be achieved when the first magnet M1 is provided in the first arm unit 12.

In the above-described imaging device 1, the first magnetic sensor S1 and the first magnet M1 are disposed close to the first pivoting axis AX1.

When the first magnetic sensor S1 and the first magnet M1 are disposed close to the first pivoting axis AX1, the first magnetic sensor S1 is disposed close to the first magnet M1.

That is, since the magnetic field released from the first magnet M1 easily influences the first magnetic sensor S1, the positional relation between the display support unit 5 and the first arm unit 12 can be detected accurately. Since the first magnetic sensor S1 is easily influenced by the magnetic field released from the first magnet M1, the first magnetic sensor S1 is relatively less influenced by another magnet disposed at another location. Thus, the positional relation between the display support unit 5 and the first arm unit 12 can be measured more accurately.

In the above-described imaging device 1, a distance between the first pivoting axis AX1 and the first magnetic sensor S1 may be equal to or less than half of a distance between the first pivoting axis AX1 and a free end of the display support unit 5 with respect to the first pivoting axis AX1.

For example, when the imaging device 1 includes another magnet different from the first magnet M1, it is easy to have an arrangement in which the magnet closest to the first magnetic sensor S1 is always the first magnet M1.

Thus, since the first magnetic sensor S1 is most easily influenced by the magnetic field of the first magnet M1, the positional relation between the display support unit 5 and the first arm unit 12 can be measured more accurately.

The above-described imaging device 1 may include the control unit 100 configured to perform display control of the image. The control unit 100 may perform display control of the display unit 4 based on the signal output by the first magnetic sensor S1 and the signal output by the second magnetic sensor S2.

When the display control of the display unit 4 is performed with switching of the photographic mode, an image appropriate for the photographic mode is displayed on the display unit 4.

For example, an operator (an icon) or the like appropriate for the photographic mode can be displayed or a direction or the like of the display of the operator can be displayed appropriately. Accordingly, it is possible to perform display appropriate for the shooting posture of the user and provide an environment in which it is easy to capture a captured image in accordance with a photographic intention. The direction of the displayed captured image can also be set to be appropriate. Thus, it is possible to guarantee a satisfactory photographic environment.

The above-described imaging device 1 may include the control unit 100 configured to perform display control of the image. The control unit 100 may perform display control to reversely display an image displayed on the display unit 4 based on the signal output by the first magnetic sensor S1 and the signal output by the second magnetic sensor S2.

The direction of the captured image displayed on the display unit 4 can be set to be appropriate in accordance with switching of the photographic mode.

Thus, the appropriate display in accordance with the photographic intention of the user is performed on the display unit 4, and it is possible to provide the imaging device 1 conveniently used by the user.

In the above-described imaging device 1, the first magnetic sensor S1 and the second magnetic sensor S2 may be different types of magnetic sensors.

Thus, appropriate disposition can be realized in accordance with the types of magnetic sensors.

Accordingly, by using the magnetic sensor appropriate for a member in which the first magnetic sensor S1 or the second magnetic sensor S2 is disposed, specifically, the shape of each of the display support unit 5, the first arm unit 12, the second arm unit 13, or the body unit 2, it is possible to achieve the thinness of each member or improve the degree of design freedom.

Since an appropriate attitude can be detected based on a property of the magnetic sensor, it is possible to switch the photographic mode at an appropriate timing or display an appropriate image in accordance with the shooting posture with high accuracy.

In the above-described imaging device 1, the first magnetic sensor S1 may be an MR sensor (for example, a magnetoresistive element) and the second magnetic sensor S2 may be a Hall sensor (a sensor in which a Hall element is used).

When a known technology is used as a plurality of types of magnetic sensors, it is not necessary to examine basic characteristics to ascertain performance of each sensor and it is possible to reduce design cost. Since a magnetic sensor cheaper than a magnetic sensor in which a novel technology is used can be used, it is possible to achieve a reduction in cost.

In the above-described imaging device 1, the second magnetic sensor S2 may be provided in the body unit 2 and the second magnet M2 may be provided in the second arm unit 13.

Compared to the case in which the second magnetic sensor S2 is provided in the second arm unit 13, thinness of the second arm unit 13 can be achieved when the second magnet M2 is provided in the second arm unit 13.

In the above-described imaging device 1, the second magnetic sensor S2 and the second magnet M2 may be disposed close to the second pivoting axis AX2.

When the second magnetic sensor S2 and the second magnet M2 are disposed close to the second pivoting axis AX2, the second magnetic sensor S2 is disposed close to the second magnet M2.

That is, since the magnetic field released from the second magnet M2 easily influences the second magnetic sensor S2, the positional relation between the body unit 2 and the second arm unit 13 can be detected accurately. Since the second magnetic sensor S2 is easily influenced by the magnetic field released from the second magnet M2, the second magnetic sensor S2 is relatively less influenced by another magnet disposed at another location. Thus, the positional relation between the body unit 2 and the second arm unit 13 can be measured more accurately.

In the above-described imaging device 1, a distance between the second pivoting axis AX2 and the second magnetic sensor S2 is equal to or less than half of a distance between the second pivoting axis AX2 and a free end of the second arm unit 13 with respect to the second pivoting axis AX2.

For example, when the imaging device 1 includes another magnet different from the second magnet M2, it is easy to have an arrangement in which the magnet closest to the second magnetic sensor S2 is always the second magnet M2.

Thus, since the second magnetic sensor S2 is most easily influenced by the magnetic field of the second magnet M2, the positional relation between the body unit 2 and the second arm unit 13 can be measured more accurately.

In the above-described imaging device 1, the display support unit 5 may be movable between an unfolded position of being unfolded with respect to the body unit 2 (for example, a position in the fully unfolded state) and a folded position of being folded with respect to the body unit 2 (for example, a position in a fully housed state). The second magnetic sensor S2 may be disposed at a position not superimposed with the first magnet M1 in a front view of the display unit 4 at the folded position of the display support unit 5. The front view mentioned here indicates a state in which the display unit 4 is faced on the rear surface side. That is, the non-superimposition in the front view of the display unit 4 indicates that the x and y coordinates of the second magnetic sensor S2 and the first magnet M1 are disposed at different positions when the horizontal direction and the orthogonal direction of the image displayed on the display unit 4 are the x and y axes. The same goes for description “not superimposed in a front view” to be described below.

The folded position is, for example, a position at which the second arm unit 13, the first arm unit 12, and the display support unit 5 are all housed in the body unit 2 (that is, a fully housed position). In other words, the folded position can also be said to be a state in which the second arm unit 13, the first arm unit 12, and the display support unit 5 are integrated with the body unit 2.

The folded position is a position at which the second magnetic sensor S2 and the first magnet M1 are not superimposed, and thus the magnetic field released from the first magnet M1 rarely influences the second magnetic sensor S2. Therefore, the influence of the magnetic field by the second magnet M2 can be correctly detected by the second magnetic sensor S2, and thus it is possible to ascertain the positional relation between the body unit 2 and the second arm unit 13 accurately.

The above-described imaging device 1 may include the third magnet M3 provided in one of the body unit 2 and the display support unit 5 and the third magnetic sensor S3 provided in the other of the body unit 2 and the display support unit 5. The third magnetic sensor S3 may receive a magnetic field released from the third magnet M3 and output a signal in accordance with the distance between the body unit 2 and the display support unit 5.

For example, a state in which the body unit 2 is closest or not close to the display support unit 5 can be detected in accordance with the signal output by the third magnetic sensor S3.

Thus, for example, it is possible to detect a low-angle photographic state.

In the above-described imaging device 1, the display support unit 5 may be movable between an unfolded position of being unfolded with respect to the body unit 2 (for example, a position in the fully unfolded state) and a folded position of being folded with respect to the body unit 2 (for example, a position in a fully housed state). The third magnetic sensor S3 may be disposed at a position not superimposed with the first magnet M1 and the second magnet M2 in a front view of the display unit 4 at the folded position of the display support unit 5.

In the folded position, the third magnetic sensor S3 is disposed at the position not superimposed with the first magnet M1 and the second magnet M2. Thus, the influence of the magnetic fields of the first magnet M1 and the second magnet M2 on the third magnetic sensor S3 is small.

That is, since the influence of the magnetic field from the third magnet M3 on the third magnetic sensor S3 can be relatively large, the open or closed state of the body unit 2 and the display support unit 5 can be ascertained more accurately.

The above-described imaging device 1 may include a metal unit (the metal plate 20) provided in one of the body unit 2 and the display support unit 5; and the fourth magnet M4 provided in the other of the body unit 2 and the display support unit 5. The display support unit 5 may be movable between an unfolded position of being unfolded with respect to the body unit 2 (for example, a position in the fully unfolded state) and a folded position of being folded with respect to the body unit (for example, a position in a fully housed state). The fourth magnet M4 may be disposed at a position not superimposed with the first magnetic sensor S1, the second magnetic sensor S2, and the third magnetic sensor S3 in a front view of the display unit 4 at the folded position of the display support unit 5.

When the metal unit (the metal plate 20) and the fourth magnet M4 corresponding thereto are provided, the display support unit 5 can be reliably housed in the body unit 2. Since the display support unit 5 can be prevented from being unnecessarily unfolded in the body unit 2, the display support unit 5 or the display unit can be prevented from being scratched, for example.

Further, in the folded position, the fourth magnet M4 is at the position not superimposed with any of the first, second, and third magnetic sensors (S1, S2, and S3), and thus the influence of the magnetic field of the fourth magnet M4 on the first, second, and third magnetic sensors (S1, S2, and S3) can be set to be small. Thus, since the influence of the magnetic field of the first magnet M1 on the first magnetic sensor S1, the influence of the magnetic field of the second magnet M2 on the second magnetic sensor S2, or the influence of the magnetic field of the third magnet M3 on the third magnetic sensor S3 can be relatively large, each pivoting state or an open state can be ascertained more accurately.

The above-described imaging device 1 may include the flexible substrate 21 electrically connecting the display unit 4 to the body unit 2. The first magnetic sensor 51 may be connected to the flexible substrate 21.

For example, the flexible substrate 21 is wired along the first arm unit 12 and the second arm unit 13, the flexible substrate 21 is bent and stretched in accordance with the pivoting state of the first arm unit 12 and the second arm unit 13.

Thus, in an imaging operation, the flexible substrate 21 is not interrupted and a probability of scratch or damage occurring in the flexible substrate 21 can be reduced.

The first magnetic sensor S1 is connected to the flexible substrate 21 formed along the display support unit 5 or the first arm unit 12, a wiring for the first magnetic sensor S1 can be shortened, and thus contribution to a reduction in cost can be achieved. Since wiring can be processed easily, it is possible to improve the degree of design freedom or achieve a reduction in design cost.

In each of the above-described examples, the angle formed between the first arm unit 12 and the second arm unit 13 is 82 degrees at a maximum, but can be pivoted more. In this case, by providing a magnet or a magnetic sensor detecting that an angle between the first arm unit 12 and the second arm unit 13 is less than a predetermined angle, it is possible to detect the selfie mode appropriately. In other words, in this configuration, since the angle formed between the first arm unit 12 and the second arm unit 13 is the predetermined angle (for example, 82 degrees) at a maximum, a magnet or a magnetic sensor detecting an angle between the first arm unit 12 and the second arm unit 13 is not necessary, and thus it is possible to achieve a reduction in the number of components, a reduction in cost, and a reduction in the number of assembly processes.

In each of the above-described examples, even when the S pole and the N pole are provided in a reverse direction in each magnet (the first magnet M1, the second magnet M2, the third magnet M3, and the fourth magnet M4) included in the imaging device 1, it is possible to obtain the above-described various advantageous effects.

The advantages effects described in the present specification are merely exemplary and other advantages effects may be obtained.

### 8. Present Technology

The present technology can be configured as follows.

(1)

An imaging device including:

a display support unit configured to support a display unit that displays an image captured by a body unit;

a first arm unit of which one end is connected to the display support unit;

a first magnet provided in one of the display support unit and the first arm unit; and

a first magnetic sensor provided in the other of the display support unit and the first arm unit, wherein

a pivoting state of the display support unit and the first arm unit is variable using a first pivoting axis as a support point axis, and

the first magnetic sensor receives a magnetic field released from the first magnet and outputs a signal in accordance with the pivoting state of the display support unit and the first arm unit.

(2)

The imaging device according to (1), including:

a second arm unit of which one end is connected to the body unit;

a second magnet provided in one of the body unit and the second arm unit; and

a second magnetic sensor provided in the other of the body unit or the second arm unit, wherein

a pivoting state of the body unit and the second arm unit is variable using a second pivoting axis as a support point axis, and

the second magnetic sensor receives a magnetic field released from the second magnet and outputs a signal in accordance with the pivoting state of the body unit and the second arm unit.

(3)

The imaging device according to (2), wherein the other end which is opposite to the one end of the second arm unit is connected to the other end which is opposite to the one end of the first arm unit.

(4)

The imaging device according to (2) or (3), wherein the first magnetic sensor outputs a signal in accordance with a positional relation between the first magnetic sensor and the first magnet changing with a change in the pivoting state of the display support unit and the first arm unit.

(5)

The imaging device according to (4), wherein the second magnetic sensor outputs a signal in accordance with a positional relation between the second magnetic sensor and the second magnet changing with a change in the pivoting state of the body unit and the second arm unit.

(6)

The imaging device according to (5), wherein the first magnetic sensor is provided in the display support unit and the first magnet is provided in the first arm unit.

(7)

The imaging device according to (5) or (6), wherein the first magnetic sensor and the first magnet are disposed close to the first pivoting axis.

(8)

The imaging device according to any one of (5) to (7), wherein a distance between the first pivoting axis and the first magnetic sensor is equal to or less than half of a distance between the first pivoting axis and a free end of the display support unit with respect to the first pivoting axis.

(9)

The imaging device according to any one of (5) to (8), including:

a control unit configured to perform display control of the image, wherein the control unit performs display control of the display unit based on the signal output by the first magnetic sensor and the signal output by the second magnetic sensor.

(10)

The imaging device according to any one of (5) to (9), including:

a control unit configured to perform display control of the image, wherein the control unit performs display control to reversely display an image displayed on the display unit based on the signal output by the first magnetic sensor and the signal output by the second magnetic sensor.

(11)

The imaging device according to any one of (5) to (10), wherein the first and second magnetic sensors are different types of magnetic sensors.

(12)

The imaging device according to (11), wherein the first magnetic sensor is an MR sensor and the second magnetic sensor is a Hall sensor.

(13)

The imaging device according to any one of (5) to (12), wherein the second magnetic sensor is provided in the body unit and the second magnet is provided in the second arm unit.

(14)

The imaging device according to any one of (5) to (13), wherein the second magnetic sensor and the second magnet are disposed close to the second pivoting axis.

(15)

The imaging device according to any one of (5) to (14), wherein a distance between the second pivoting axis and the second magnetic sensor is equal to or less than half of a distance between the second pivoting axis and a free end of the second arm unit with respect to the second pivoting axis.

(16)

The imaging device according to any one of (5) to (15), wherein
the display support unit is movable between an unfolded position of being unfolded with respect to the body unit and a folded position of being folded with respect to the body unit, and
the second magnetic sensor is disposed at a position not superimposed with the first magnet in a front view of the display unit at the folded position of the display support unit.

(17)

The imaging device according to any one of (5) to (16), including:
a third magnet provided in one of the body unit and the display support unit; and
a third magnetic sensor provided in the other of the body unit and the display support unit, wherein
the third magnetic sensor receives a magnetic field released from the third magnet and outputs a signal in accordance with a distance between the body unit and the display support unit.

(18)

The imaging device according to (17), wherein
the display support unit is movable between an unfolded position of being unfolded with respect to the body unit and a folded position of being folded with respect to the body unit, and
the third magnetic sensor is disposed at a position not superimposed with the first and second magnets in a front view of the display unit at the folded position of the display support unit.

(19)

The imaging device according to (17) or (18), including:
a metal unit provided in one of the body unit and the display support unit; and
a fourth magnet provided in the other of the body unit and the display support unit,
wherein
the display support unit is movable between an unfolded position of being unfolded with respect to the body unit and a folded position of being folded with respect to the body unit, and
the fourth magnet is disposed at a position superimposed with none of the first, second, and third magnetic sensors in a front view of the display unit at the folded position of the display support unit.

(20)

The imaging device according to any one of (1) to (19), further including: a flexible substrate electrically connecting the display unit to the body unit, wherein the first magnetic sensor is connected to the flexible substrate.

### REFERENCE SIGNS LIST

1 Imaging device

2 Body unit

4 Display unit

5 Display support unit

12 First arm unit

13 Second arm unit

20 Metal plate (metal unit)

21 Flexible substrate

100 Control unit

AX1 First pivoting axis

AX2 Second pivoting axis

AX3 Third pivoting axis

M1 First magnet

M2 Second magnet

M3 Third magnet

M4 Fourth magnet

S1 First magnetic sensor

S2 Second magnetic sensor

S3 Third magnetic sensor

1. An imaging device comprising:
a display support unit configured to support a display unit that displays an image captured by a body unit;
a first arm unit of which one end is connected to the display support unit;
a first magnet provided in one of the display support unit and the first arm unit; and
a first magnetic sensor provided in the other of the display support unit and the first arm unit, wherein
a pivoting state of the display support unit and the first arm unit is variable using a first pivoting axis as a support point axis, and
the first magnetic sensor receives a magnetic field released from the first magnet and outputs a signal in accordance with the pivoting state of the display support unit and the first arm unit.

2. The imaging device according to claim 1, comprising:
a second arm unit of which one end is connected to the body unit;
a second magnet provided in one of the body unit and the second arm unit; and
a second magnetic sensor provided in the other of the body unit and the second arm unit, wherein
a pivoting state of the body unit and the second arm unit is variable using a second pivoting axis as a support point axis, and
the second magnetic sensor receives a magnetic field released from the second magnet and outputs a signal in accordance with the pivoting state of the body unit and the second arm unit.

3. The imaging device according to claim 2, wherein the other end which is opposite to the one end of the second arm unit is connected to the other end which is opposite to the one end of the first arm unit.

4. The imaging device according to claim 2, wherein the first magnetic sensor outputs a signal in accordance with a positional relation between the first magnetic sensor and the first magnet changing with a change in the pivoting state of the display support unit and the first arm unit.

5. The imaging device according to claim 4, wherein the second magnetic sensor outputs a signal in accordance with a positional relation between the second magnetic sensor and the second magnet changing with a change in the pivoting state of the body unit and the second arm unit.

6. The imaging device according to claim 5, wherein the first magnetic sensor is provided in the display support unit and the first magnet is provided in the first arm unit.

7. The imaging device according to claim 5, wherein the first magnetic sensor and the first magnet are disposed close to the first pivoting axis.

8. The imaging device according to claim 5, wherein a distance between the first pivoting axis and the first magnetic sensor is equal to or less than half of a distance between the first pivoting axis and a free end of the display support unit with respect to the first pivoting axis.

9. The imaging device according to claim 5, comprising:
a control unit configured to perform display control of the image, wherein
the control unit performs display control of the display unit based on the signal output by the first magnetic sensor and the signal output by the second magnetic sensor.

10. The imaging device according to claim 5, comprising:
a control unit configured to perform display control of the image, wherein
the control unit performs display control to reversely display an image displayed on the display unit based on the signal output by the first magnetic sensor and the signal output by the second magnetic sensor.

11. The imaging device according to claim 5, wherein the first and second magnetic sensors are different types of magnetic sensors.

12. The imaging device according to claim 11, wherein the first magnetic sensor is an MR sensor and the second magnetic sensor is a Hall sensor.

13. The imaging device according to claim 5, wherein the second magnetic sensor is provided in the body unit and the second magnet is provided in the second arm unit.

14. The imaging device according to claim 5, wherein the second magnetic sensor and the second magnet are disposed close to the second pivoting axis.

15. The imaging device according to claim 5, wherein a distance between the second pivoting axis and the second magnetic sensor is equal to or less than half of a distance between the second pivoting axis and a free end of the second arm unit with respect to the second pivoting axis.

16. The imaging device according to claim 5, wherein
the display support unit is movable between an unfolded position of being unfolded with respect to the body unit and a folded position of being folded with respect to the body unit, and
the second magnetic sensor is disposed at a position not superimposed with the first magnet in a front view of the display unit at the folded position of the display support unit.

17. The imaging device according to claim 5, comprising:
a third magnet provided in one of the body unit and the display support unit; and
a third magnetic sensor provided in the other of the body unit and the display support unit, wherein
the third magnetic sensor receives a magnetic field released from the third magnet and outputs a signal in accordance with a distance between the body unit and the display support unit.

18. The imaging device according to claim 17, wherein
the display support unit is movable between an unfolded position of being unfolded with respect to the body unit and a folded position of being folded with respect to the body unit, and
the third magnetic sensor is disposed at a position not superimposed with the first and second magnets in a front view of the display unit at the folded position of the display support unit.

19. The imaging device according to claim 17, comprising:
a metal unit provided in one of the body unit and the display support unit; and
a fourth magnet provided in the other of the body unit and the display support unit,
the display support unit is movable between an unfolded position of being unfolded with respect to the body unit and a folded position of being folded with respect to the body unit, and
the fourth magnet is disposed at a position superimposed with none of the first, second, and third magnetic sensors in a front view of the display unit at the folded position of the display support unit.

20. The imaging device according to claim 1, comprising:
a flexible substrate electrically connecting the display unit to the body unit,
wherein
the first magnetic sensor is connected to the flexible substrate.
